(19) United States
(12) Patent Application Publication
(10) Pub. No.: US 2017/0194721 A1
(43) Pub. Date: Jul. 6, 2017

(54) Electrical Connector and Method of Making It

(71) Applicants: Chih-Peng Fan, Tao-Yuan City (TW); Ching-Ho Hsieh, Tao-Yuan City (TW); Min-Hsing Wu, Tao-Yuan City (TW); David L. Chen, Los Altods, CA (US); Woody James Maynard, State College, PA (US)

(72) Inventors: Chih-Peng Fan, Tao-Yuan City (TW); Ching-Ho Hsieh, Tao-Yuan City (TW); Min-Hsing Wu, Tao-Yuan City (TW); David L. Chen, Los Altods, CA (US); Woody James Maynard, State College, PA (US)

(21) Appl. No.: 15/401,027

(22) Filed: Jan. 7, 2017

Related U.S. Application Data
(60) Provisional application No. 62/275,720, filed on Jan. 6, 2016.

(51) Int. Cl. H01R 4/04; H05K 3/32; H01R 13/24; H01R 12/52; H01R 12/57

(52) U.S. Cl. CPC H01R 4/04; H01R 12/52; H01R 12/57; H01R 13/2407; H05K 3/326

(57) ABSTRACT

A novel electrical connector and method of manufacture is disclosed which provides an integral attachment and retention means for the purpose of electrically and mechanically interconnecting circuit elements in electronic devices, said circuit elements including but not limited to printed circuit boards, flexible printed circuits, rigid flex circuits, semiconductor package substrates, modules, and batteries. The electrical connector of the present invention utilizes a bonding material, disposed at least between the electrical spring contact elements on a surface of the connector, to bond and retain first and second portions of the electrical connector in an actuated state on a mating circuit element whereby stable and low resistance electrical interconnections are formed and maintained between the electrical connector and interconnection terminals on the mating circuit element. This design permits the electrical connector to be low-profile and use a reduced amount of space on a circuit member such as a PCB.

### CROSS-REFERENCE TO RELATED PATENTS

The present patent application claims the benefit of provisional patent application Ser. No. 62/275,720 filed Jan. 7, 2016 and entitled “Low Profile Self-Clamping Normal Force Electrical Connector and Method of Manufacture”. The specification and drawings of this provisional patent application are hereby incorporated herein by reference.

### BACKGROUND

Field of the Invention

The present invention relates to electrical connectors, including separable electrical connectors, used for the interconnection of circuit elements in products such as computers, mobile phones, tablets, laptop computers, digital cameras, medical electronics devices, optoelectronic assemblies, sensors, transducers, automotive electronic assemblies, aerospace electronic assemblies, industrial electronics, or other electronic devices, systems or subsystems, or products containing discrete electronic elements requiring electrical interconnection.

Background of the Invention

Complex electronic devices such as computers and mobile phones require electrical interconnection of various circuit elements, such as printed circuit boards (PCB), flexible printed circuit (FPC) cables, rigid-flex circuits, ceramic substrates, semiconductor package substrates, optoelectronic devices, batteries, and other elements of electronic devices. Frequently, it is desired that these interconnections be separable in order to facilitate low cost and simplified assembly, test, rework, and repair, or to avoid high temperature interconnection methods such as soldering, brazing, or other high temperature attachment methods when certain subcomponents or elements of the assembly are sensitive to elevated temperatures, or for other reasons or combinations of reasons.

For this reason, there is frequently a plurality of separable electrical connectors found in a single electronic device. As these electronic devices evolve to provide increased functionality in smaller form factors, such as for mobile consumer electronic products, the electrical connectors must simultaneously improve in function and performance while decreasing in size, including area of the connector's footprint (x by y area occupied on the mating circuit elements) and its profile (thickness). Low profile connectors also facilitate reduced electrical resistance across the connector, allowing them to carry more power with less temperature increase due to resistive losses, and often enable better signal integrity due to lower inductance and reduced impedance discontinuity.

It is frequently required that these electrical connectors meet stringent performance requirements, such as maintaining high signal integrity of the interconnected electronic signals at high operating frequencies, providing low electrical contact resistance to enable high current capacity with minimal temperature rise, surviving high levels of mechanical shock and vibration without transient or permanent interruptions in the electrical path, maintaining reliable interconnections through various environmental stresses during life of the product, and meeting other stringent performance requirements that are specific to various applications such as aerospace, medical electronics, and other demanding applications. As electronic devices continue to be miniaturized, the interconnection terminals or pads on the circuit elements requiring interconnection are commonly required to be reduced in size (area) and located on finer pitches (spaced closer together), necessitating electrical connectors with improved means for precise and accurate alignment to the circuit elements and with very accurate true position of the contacts in the connector relative to each other and to the position of these alignment means. Manufacturing costs of these connectors must be low to keep pace with the competitive environment and end-product pricing constraints, so connector materials and manufacturing processes must be simple, streamlined and/or low cost.

Some of the better performing connectors with respect to the above criteria are normal force connectors. Normal force connectors typically have electrical spring contact elements emanating from a first surface of the electrical connector. A second, opposing surface may also have electrical spring contact elements emanating from it, or it may have electrical interconnection terminals that are adapted for a different means of assembly and interconnection, such as surface mount soldering. Typically, one or more of the electrical spring contact elements on the first surface of the normal force connector are electrically interconnected to at least one of the electrical spring contacts or interconnection terminals on the second surface of the normal force connector. The electrical spring contact elements of normal force connectors can be modified cantilever beam-like springs, such as in the Neoconix PCBeam™ normal force connectors, or they can be surface-emanating coil springs, or pogo pins, or other springs that are compressed and actuated against a mating conductive terminal by application of force normal to the mating surfaces of the connector and of the mating circuit element. In the case of the PCBeam™ connector, the spring contacts are similar to a cantilever beam spring, as described in a number of US patents including the following:

U.S. Pat. No. 7,371,073 entitled “Contact Grid Array”, issued May 13, 2008, to inventor John David Williams and assigned to Neoconix, Inc., the assignee of the present patent; this patent is sometimes referred to herein as the “Contact Array Patent”, the disclosure of which is incorporated by reference in its entirety;

U.S. Pat. No. 7,056,131 entitled “Contact Grid Array System”, issued Jun. 6, 2006, to inventor John David Williams and assigned to Neoconix, Inc., the assignee of the present patent, the disclosure of which is incorporated by reference in its entirety;

U.S. Pat. No. 7,758,351 entitled “Method and System for Batch Forming of Spring Elements” issued Jul. 20, 2010, to inventors Dirk D. Brown et al. and also assigned to Neoconix, Inc.; this patent is sometimes referred to herein as the “Batch Forming Patent”, the disclosure of which is incorporated by reference in its entirety.

Normal force connectors frequently perform well at surviving mechanical shock and vibration forces which can be experienced during normal use of mobile electronic devices without transient or permanent interruptions in the electrical path, because the retention of the connector in its compressed, actuated state is typically positive to the extent that any potential separation between the connector and the mating circuit element due to these shock or vibration forces is less than the working range of the electrical spring contacts of the connector. In contrast, connectors such as two-piece, mezzanine board to board connectors rely on lateral friction between mating spring elements to provide retention, and ZIF connectors rely on a nonpositive cam-action lid. For this reason, secondary retention mechanisms, such as tape over a ZIF connector lid or a secondary clamp over a board to board mezzanine connector, are frequently implemented. Since space in miniaturized devices is at a premium, this is not ideal. As these connectors continue to be miniaturized to fit into shrinking device form factors, the sensitivity to shock and vibration typically increases due to reduced area for application of retention forces. Frequently, the profile (thickness) of these connectors is well above 1 millimeter, which can be a limiting factor in shrinking the thickness of devices like high end mobile ‘smart-phones’. It is desirable and would be an advance over the current state of the art to provide a connector structure, affixing means, and method of manufacture that offers high signal fidelity interconnections, high mechanical and electrical compliance and working range of the electrical spring contacts, high resistance to mechanical shock and vibration, fine contact pitch, a small footprint for the connector and its retention mechanism, and low connector profile, among other desirable attributes. It would be a further advantage to have electrical connectors with the above advantages, and which could be permanently or semipermanently affixed to at least one of two mating circuit elements being electrically interconnected, such as a PCB or an FPC, without requiring a surface mount assembly process such as a solder reflow based process or a conductive adhesive based process, which have their own inherent reliability issues—such as susceptibility to joint failure under conditions of device dropping, shock and/or vibration—and processing costs and complexities. It would also be a further advantage to avoid the requirement for a complex mechanical mounting and compression mechanism, such as a socket frame and lid, screws, or mechanical clamps, each of which requires substantial use of substrate real estate and may require holes or other penetrations through the substrate that impact substrate wiring density on multiple circuit layers.

### SUMMARY OF INVENTION

I. While aspects of the subject matter of the present disclosure may be embodied in a variety of forms, the following description and accompanying drawings are merely intended to disclose some of these forms as specific examples of the subject matter. Accordingly, the subject matter of this disclosure is not intended to be limited to the forms or embodiments so described and illustrated.
II. Unless defined otherwise, all terms of art, notations and other technical terms or terminology used herein have the same meaning as is commonly understood by one of ordinary skill in the art to which this disclosure belongs. All patents, applications, published applications and other publications referred to herein are incorporated by reference in their entirety. If a definition set forth in this section is contrary to or otherwise inconsistent with a definition set forth in the patents, applications, published applications, and other publications that are herein incorporated by reference, the definition set forth in this section prevails over the definition that is incorporated herein by reference.
III. Unless otherwise indicated or the context suggests otherwise, as used herein, “a” or “an” means “at least one” or “one or more.”
IV. This description may use relative spatial and/or orientation terms in describing the position and/or orientation of a component, apparatus, location, feature, or a portion thereof. Unless specifically stated, or otherwise dictated by the context of the description, such terms, including, without limitation, top, bottom, above, below, under, on top of, upper, lower, left of, right of, in front of, behind, next to, adjacent, between, horizontal, vertical, diagonal, longitudinal, transverse, radial, axial, etc., are used for convenience in referring to such component, apparatus, location, feature, or a portion thereof in the drawings and are not intended to be limiting.
V. Furthermore, unless otherwise stated, any specific dimensions mentioned in this description are merely representative of an exemplary implementation of a device embodying aspects of the disclosure and are not intended to be limiting.

The present disclosure relates to electrical connectors for interconnecting circuit elements in an electronic device or subsystem.

One objective of the present invention is to provide a low profile, high performance electrical interconnection means for electrically interconnecting, in a reliable fashion, two circuit elements in an electronic system or device, such circuit elements including but not limited to two printed circuit boards, or a printed circuit board and a flexible printed circuit, or a semiconductor package substrate and a printed circuit board, or a rigid-flex circuit and a flexible or rigid printed circuit, or a socket to a printed circuit board, or a modular subsystem such as a cell phone camera or a sensor to a mating circuit element such as an FPC or a PCB.

It is another objective of the present invention to provide an electrical connector in a form that enables easy and low cost assembly in high volume.

It is a further objective of the present invention to provide an electrical connector which can be permanently or semi-permanently assembled to a mating circuit element. The phrase ‘permanently or semi-permanently assembled to a mating circuit element’, means that the connector is assembled to and retained on a mating circuit element in its compressed and actuated state, whereby a low electrical resistance interconnection is achieved and maintained between the electrical spring contacts on the connector and the respective electrical spring contact terminals on a mating circuit element until purposefully de-mated.

It is another objective of the present invention to thereby simplify further assembly of the electronic device by having one mating surface of the electrical connector actuated and permanently affixed to one circuit element in an electronic assembly. It is a further objective of this invention to provide an electrical connector which can be permanently or semipermanently assembled to a mating circuit element at temperatures less than those required for reflow of eutectic tin lead solders or lead-free solders, given that such elevated assembly temperatures can cause damage to certain sensitive components or devices, such as some optoelectronic assemblies, flash memory devices, MEMS devices, or other temperature sensitive elements in an electronic device or subsystem.

It is a further objective of this invention to provide an electrical connector which can be permanently or semi-permanently assembled to a mating circuit element in a simple fashion which is compatible with high volume, low cost manufacturing.

It is a further objective of this invention to provide an electrical connector which can be permanently or semi-permanently assembled to a mating circuit element without requiring complex and costly tooling.

It is a further objective of this invention to provide an electrical connector which can be permanently or semi-permanently assembled to a mating circuit element such as an FPC or a PCB and which can be assembled and interconnected to that circuit element without requiring any additional hardware or tooling to retain the connector in its compressed and actuated state.

It is a further objective of this invention to provide an electrical connector which can be permanently or semi-permanently assembled to a mating circuit element such as an FPC or a PCB and which can be assembled and interconnected to that circuit element without occupying substantial additional real estate on the connector beyond that which is occupied by the electrical contact elements of the connector itself, so as to facilitate miniaturization and cost reduction of the connector.

It is a further objective of this invention to provide an electrical connector which can be permanently or semi-permanently assembled to a mating circuit element without requiring perforations in the mating circuit element for the purpose of retaining and compressing the connector on the circuit element.

Another objective of the present invention is to provide such a connector also comprising electrical spring contacts having a high degree of mechanical and electrical compliance, thereby providing the interconnection with a high tolerance of mechanical shock and vibration without suffering transient or permanent opens.

In an embodiment of the present invention, an electrical connector with a plurality of conductive spring contacts is retained on a mating circuit element with the conductive spring contacts in a compressed state against mating conductive circuit terminals using an integral attaching material, such that low resistance electrical interconnections are created and maintained between the conductive spring contacts of the electrical connector and mating conductive terminals on the mating circuit element.

In one embodiment, the integral attaching material is a bonding material.

In one embodiment, the integral attaching material is a non-conductive bonding material.

In one embodiment, the integral attaching material is a polymer.

In one embodiment, the integral attaching material is a thermo-plastic polymer.

In one embodiment, the integral attaching material is a thermo-setting polymer.

In one embodiment, the integral attaching material is an adhesive.

In one embodiment, the integral attaching material is an epoxy.

In one embodiment, the integral attaching material is a modified acrylic adhesive.

In one embodiment, the integral attaching material is a sheet adhesive.

In one embodiment, the integral attaching material is a pressure sensitive adhesive.

In one embodiment, the integral attaching material is a homogeneous polymer.

In one embodiment, the integral attaching material is a heterogeneous material, such as an adhesive stabilized by a second material, such as a polyimide film.

In one embodiment, the integral material is a heterogeneous material, such as a bond ply material. In a further embodiment, the bond ply material is comprised of a B-staged, modified acrylic adhesive on both, opposing surfaces of a polyimide film. In one embodiment, the bond ply material is DuPont Pyralux FR bond ply material. In one embodiment, the bond ply material is DuPont Pyralux LF bond ply material.

In one embodiment, the integral attaching material has a plurality of openings corresponding to, and substantially aligned with, the distal ends of the electrical contact springs of an electrical connector.

In one embodiment, the integral attaching material is disposed upon the proximal end of an electrical spring contact, and has one or more openings through which the distal ends of electrical spring contacts emanate.

In an embodiment of the present invention, an electrical connector with a plurality of conductive spring contacts is retained, using a bonding material, on a mating circuit element with the conductive spring contacts in a compressed state and resisting upon electrically conductive terminals on the mating circuit element, such that low resistance electrical interconnections between the electrical spring contacts and the mating conductive terminals on the mating circuit element are obtained. In a further embodiment, the bonding material has clearance openings for the elastic portion of the conductive spring contacts.

In one embodiment, the connector is a normal force connector, and a low resistance electrical interconnection is achieved by applying a force on the connector normal to the surface of the mating circuit element and maintaining that force using a bonding material.

In one embodiment, the connector is a Neoconix PCBeam™ connector. In another embodiment, the connector is a Neoconix XBeam™ connector.

In one embodiment, the electrical spring contacts in their uncompressed state stand proud of the outer surface of the bonding material.

In one embodiment, the bonding material also serves as a hard compression stop to limit the travel of the electrical spring contacts, so as to prevent over-compression of the springs that might otherwise cause plastic deformation, cracking, or other damage.

It should be realized that not all embodiments of the present invention will achieve all of the objectives set forth above—and that the invention may have additional advantages and objectives beyond what are stated in this patent application. One of ordinary skill in the relevant art will understand the principles of the present invention from this document and may choose to achieve some of the objects without achieving other objects and may choose to include certain features of the present invention without employing other features. As such, the discussion of the objectives is for example of the present invention and not in limitation thereof or any implication that all of the objectives have to be met to practice the present invention.

### BRIEF DESCRIPTION OF THE DRAWINGS

FIG. 1 shows a drawing of a perspective view of a prior art connector, and specifically a ZIF normal force connector for interconnecting an FPC to a PCB.

FIG. 2 shows a drawing of a perspective view of a prior art connector, requiring mechanical affixing means.

FIG. 3 shows a drawing of a perspective view of a prior art connector, requiring mechanical affixing means.

FIG. 4 (comprising FIG. 4a and FIG. 4b) shows drawings which compare a prior art connector with a connector of the present invention.

FIG. 5 shows a drawing of an expanded, top down view of a portion of a connector of the present invention.

FIG. 6 shows a drawing of a cross-sectional view of a portion of a connector of the present invention.

FIG. 7 shows a drawing of an expanded cross-sectional view of a portion of a connector of the present invention.

FIG. 8 shows a drawing of an expanded cross-sectional view of a portion of a connector of the present invention.

FIG. 9 shows a drawing of a perspective view of one surface of a connector of the present invention.

FIG. 10 shows a drawing of a cross-sectional view of a portion of a connector of the present invention aligned to and making initial contact with a mating circuit element, prior to full compression of the electrical spring contacts.

FIG. 11 shows a drawing of a perspective view of a portion of one surface of a connector of the present invention.

FIG. 12 shows a photograph of a cross-section of a portion of a surface mount connector of the present invention.

FIG. 13 shows a drawing of a perspective view of a prior art connector and associated attachment hardware and mating circuit elements.

FIG. 14 shows a drawing of a perspective view of a connector of the present invention and illustrating improvements relative to the prior art connector of FIG. 13.

FIG. 15 (consisting of FIG. 15a and FIG. 15b) shows a drawing of a perspective view of a connector of the present invention, prior to and following application of a bonding layer to an interconnection surface of the connector.

FIG. 16 shows a drawing of a perspective, exploded view of a connector of the present invention utilized to interconnect a module, such as a camera module or a sensor module, to a flexible printed circuit or PCB.

FIG. 17 shows a drawing of an expanded perspective view of the connector from FIG. 16.

FIG. 18 shows a drawing of a cross-sectional view of the connector from FIG. 16.

FIG. 19 shows a drawing of a perspective view of one method of manufacture of a connector of the present invention.

FIG. 20 shows a drawing of a perspective view of a connector of the present invention.

FIG. 21 shows a drawing of an expanded, top down view of an electrical contact of the connector of the present invention shown in FIG. 20.

FIG. 22 shows a drawing of a cross-sectional view of the connector of the present invention illustrated in FIG. 20.

FIG. 23 shows a drawing of a cross-sectional view of the connector illustrated in FIG. 20 being utilized to electrically interconnect two circuit elements according to the present invention.

FIG. 24 shows a drawing of a cross-sectional view of a connector of the present invention.

FIG. 25 shows a drawing of an expanded, top down view of an electrical contact of the connector of the present invention shown in FIG. 24.

FIG. 26 shows a drawing of a cross-sectional view of an alternative embodiment of the connector of the present invention illustrated in FIG. 24.

FIG. 27 shows a drawing of a cross-sectional view of the connector illustrated in FIG. 26 being utilized to electrically interconnect two circuit elements according to the present invention.

FIG. 28 (consisting of FIG. 28a and FIG. 28b) shows a drawing of a cross-sectional view of a connector of the present invention, and showing the spring contacts in un-compressed (in FIG. 28a) and compressed (in FIG. 28b) states.

FIG. 29 shows a flow chart illustrating one process involved in practicing the present invention.

### DETAILED DESCRIPTION

In an embodiment of the present invention, an electrical connector with a plurality of conductive spring contacts is retained on a mating circuit element, with the conductive spring contacts of the connector in a compressed state, using an adhesive material disposed between the connector surface and the mating circuit element, such that low resistance electrical interconnections between the conductive spring contacts and mating conductive terminals on the mating circuit element are obtained. In one embodiment, the connector is a normal force connector, and the low resistance electrical interconnection is achieved by applying a force on the connector normal to the surface of the mating circuit element and maintaining that force using an adhesive material. In one embodiment, the connector is a Neoconix PCBeam™ connector. In one embodiment, the electrical spring contacts in their uncompressed state stand proud of the outer surface of the adhesive material. In an embodiment, the adhesive material is a non-conductive adhesive. In an embodiment, the adhesive material is a polymer. In an embodiment, the adhesive material is an epoxy. In an embodiment, the adhesive material is a woven glass reinforced, B-staged epoxy. In an embodiment, the adhesive material is a sheet material. In an embodiment, the adhesive material is a modified acrylic sheet adhesive. In an embodiment, the adhesive material is a B-staged modified acrylic sheet adhesive. In an embodiment, the adhesive material is a bond ply adhesive. In an embodiment, the adhesive material is a bond ply adhesive comprised of a B-staged modified acrylic adhesive on both surfaces of a polyimide film. In an embodiment, the adhesive material is a DuPont Pyralux LF bond ply material. In a different embodiment, the adhesive material is a DuPont Pyralux FR bond ply material. In an embodiment, the bond ply adhesive has openings corresponding to the locations of the electrical spring contacts. In an embodiment, the openings in the bond ply adhesive allow compression of the electrical spring contacts against a conductive terminal on a mating circuit element without interference of the bond ply with the elastic movement of the spring contact and without its impeding the formation of low resistance electrical interconnections. In an embodiment, the electrical interconnection is comprised of the electrical spring contact of the connector compressed against a conductive terminal on the mating circuit element and retained by an adhesive material surrounding it, which adhesive material has been cured by the application of elevated temperature and pressure.

In an embodiment, the electrical interconnection is comprised of the electrical spring contact of the connector compressed against a conductive terminal on the mating circuit element and retained by an adhesive material surrounding it, said adhesive material being a pressure sensitive adhesive, and which has been bonded by the application of normal force pressure.

In an embodiment, an electrical connector having a first surface with a plurality of conductive spring contacts disposed on, and emanating from, that first surface, has a bonding material disposed on the first surface in the interstitial areas between the electrical spring contact elements. In one embodiment, the adhesive material is disposed on the first surface of the electrical connector in order to bond it to, and retain it on, a mating circuit element with the electrical spring contacts of the connector in compression against conductive terminals on the mating circuit element, so as to form low resistance electrical interconnections to mating conductive terminals on the circuit element.

In an embodiment, an electrical connector has an adhesive disposed on the surface between the electrical spring contact elements, in order to bond it to and retain it on a mating circuit element, so as to form low resistance electrical interconnections to mating conductive terminals on the circuit element.

In an embodiment, an electrical connector having electrically conductive spring contacts is electrically interconnected to an external circuit element in an actuated, compressed state using a bonding material.

In an embodiment, an electrical connector having electrically generally linear, conductive spring contacts is electrically interconnected to an external circuit element in an actuated, compressed state using an adhesive. In another embodiment, the generally linear, conductive spring contacts have an anisotropic grain structure, with the longer dimension of the grains generally parallel to the length of the conductive spring contact.

In an embodiment, an electrical connector is used to electrically interconnect two circuit elements. The electrical connector may be interconnected to a first circuit element using a bonding material to retain it on the first mating circuit element, with the electrical spring contacts of the connector in compression against conductive terminals on the mating circuit element so as to form low resistance electrical interconnections to mating conductive terminals on the circuit element. The electrical connector may be interconnected to a second circuit element separably, using mechanical means other than a bonding material to maintain it in compression against the second circuit element.

In an embodiment, an electrical connector having electrically conductive spring contacts is used to electrically interconnect two circuit elements. The electrical connector may be permanently or semi-permanently interconnected to one circuit element using a bonding material, such as an adhesive, while the electrical interconnection to a second circuit element remains separable, and is held in place and actuated using mechanical means other than an adhesive.

In an embodiment, an electrical connector having electrically conductive spring contacts is used to electrically interconnect two circuit elements. The electrical connector may be permanently or semi-permanently interconnected to one circuit element using a bonding material, such as an adhesive, while the electrical interconnection to a second circuit element is formed using a solder interconnection, such as a eutectic tin lead solder or a lead-free solder such as tin-silvercopper, or a low temperature solder, such as those containing indium or bismuth.

In an embodiment, an electrical connector is used to electrically interconnect a flexible printed circuit (FPC) to a rigid printed circuit board (PCB). The electrical connector has a first plurality of surface emanating electrical spring contacts on a first surface of the connector, and a second plurality of surface emanating electrical spring contacts on a second, opposing surface of the connector. At least one of the electrical spring contacts on the first surface of the connector is electrically interconnected to at least one of the electrical spring contacts on the second surface of the connector. The first surface of the electrical connector is permanently or semipermanently interconnected to the flexible printed circuit using a bonding material, such as an adhesive, to hold it in compression against the FPC, so as to form low resistance electrical interconnections to mating conductive terminals on the FPC. The FPC-connector assembly is interconnected separably to the PCB using mechanical means to actuate and retain the second surface of the connector against the PCB with the second plurality of electrical spring contacts held in compression against the PCB so as to form low resistance electrical connections to conductive terminals on the PCB. In one embodiment, the FPC may require a stiffener to be located on the FPC opposite the connector, in order to facilitate the application of uniform force to the connector when mating it to the PCB. The retention of the connector in compression against the rigid PCB may be accomplished with a mechanical clamp, with screws, or with other mechanical means.

In an embodiment, a normal force electrical connector, having electrical spring contacts emanating from two opposing surfaces, and electrical interconnection means from one connector surface to the opposing connector surface, is used to electrically interconnect a flexible printed circuit (FPC) to a rigid printed circuit board (PCB). The electrical connector is permanently or semi-permanently interconnected to the rigid PCB using a bonding material, such as an adhesive, to hold its elastic, electrical spring contacts in compression against the PCB, so as to form low resistance electrical interconnections to mating conductive terminals on the PCB. The PCB-connector assembly is interconnected separably to the FPC using mechanical means to actuate and retain the connector, so as to form low resistance electrical connections to the FPC. The FPC may require a stiffener to be located on the FPC opposite the connector, in order to facilitate the application of uniform force to the connector.

In an embodiment, the electrical connector is used to electrically interconnect two FPCs. The electrical connector is permanently or semi-permanently interconnected to one of the FPCs using a bonding material, such as an adhesive, to hold it in compression against the FPC and form low resistance electrical interconnections to mating conductive terminals on the FPC. The FPC-connector assembly is interconnected separably to the second FPC using mechanical means to actuate and retain the connector. The FPC may require a stiffener to be located on the FPC opposite the connector, in order to facilitate the application of uniform force to the connector.

In an embodiment, the electrical connector is used to electrically interconnect two rigid PCBs. The electrical connector is interconnected to one of the PCBs using a bonding material, such as an adhesive, to hold it in compression against the PCB and form low resistance electrical interconnections to the mating conductive terminals on the PCB. The PCB-connector assembly is then interconnected separably to the second PCB using mechanical means to actuate and retain the connector.

In an embodiment, the electrical connector is a socket which is used to electrically interconnect a semiconductor package substrate to a PCB or to an FPC. The socket may be permanently or semi-permanently interconnected to the PCB or FPC using a bonding material, such as an adhesive, to hold it in compression against the PCB, so as to form low resistance electrical interconnections to mating conductive terminals on the PCB, while the electrical interconnections between the socket and the semiconductor package remain separable.

In an embodiment, the electrical connector is used to electrically interconnect a module, such as a camera module, a sensor module, an optoelectronic transducer module, or any other type of module in an electronic device, to a PCB or to an FPC. A first surface of the connector may be permanently or semi-permanently interconnected to the module using a bonding material, such as an adhesive, to hold it in compression against the module, so as to form low resistance electrical interconnections to mating conductive terminals on the module, while the electrical interconnections between the connector and the mating FPC or PCB remain separable, and is retained in compression on the FPC or PCB by mechanical means other than a bonding adhesive.

In an embodiment, the electrical connector is used to electrically interconnect a module, such as a camera module, a sensor module, an optoelectronic transducer module, or any other type of module in an electronic device, to a PCB or to an FPC. The electrical connector may be integral to the module, in that the module components, devices, and circuits may mounted within, and/or on a first surface of, the module, and whereby the module may comprise a printed circuit board assembly or package substrate assembly or similar structure, and where the module has a plurality of conductive spring contacts which emanate from a second surface of the module, and which are electrically interconnected with the module electronics. An adhesive is disposed on the second surface of the module, with clearance openings for the conductive spring contacts, such that when the module is mated and compressed against a mating circuit element with a force normal to the mating surface of the mating circuit element, which may be a PCB or an FPC, and with the conductive spring contacts in alignment with respective conductive interconnection terminals on the mating circuit element, the electrical contact springs are compressed, and retained by the adhesive, against the conductive terminals on the mating circuit element and thereby form a low resistance electrical interconnection between the module and the circuit element.

In an embodiment, a first surface of a normal force electrical connector having surface emanating, elastic spring contacts is permanently or semi-permanently assembled to and retained on a mating circuit element in an actuated state using an adhesive material disposed between the connector and the mating circuit element in the interstitial area between the mating conductive interconnection terminals. An actuated state is defined herein as a state whereby the connector is positioned and retained in intimate contact with the mating circuit element so that the electrical spring contacts on the first surface of the connector remain in a sufficiently compressed state against the mating conductive interconnection terminals on the mating circuit element such that a low electrical resistance interconnection is achieved between the electrical spring contacts on the connector and the respective conductive interconnection terminals on the mating circuit element.

In an embodiment, an electrical connector is used to electrically interconnect a first circuit element to a second circuit element. The electrical connector has a first plurality of surface emanating electrical spring contacts on a first surface of the connector, and a second plurality of surface emanating electrical spring contacts on a second, opposing surface of the connector. At least one of the electrical spring contacts on the first surface of the connector is electrically interconnected to at least one of the electrical spring contacts on the second surface of the connector. The first surface of the electrical connector is permanently or semi-permanently interconnected to the first circuit element using a first bonding material, such as an adhesive, to hold it in compression against the first circuit element, so as to form low resistance electrical interconnections between the first plurality of spring contacts and mating conductive terminals on the first circuit element. The second surface of the electrical connector is permanently or semi-permanently interconnected to the second circuit element using a second bonding material, such as an adhesive, to hold it in compression against the second circuit element, so as to form low resistance electrical interconnections between the second plurality of spring contacts and mating conductive terminals on the second circuit element, and thereby creating an electrical interconnection between at least one conductive terminal on the first circuit element and at least one conductive terminal on the second circuit element. The first bonding material and the second bonding material may both be adhesives. The first bonding material and the second bonding material may be identical in nature, composition and properties, including thermal properties. The first bonding material and the second bonding material may be different in nature, composition and properties, such that they may bond at substantially different temperatures. The first bonding material and the second bonding material may have identical or similar glass transition temperatures. The first bonding material and the second bonding material may have substantially different glass transition temperatures. The first and second bonding materials may be thermoplastic materials with identical or similar melting temperatures. The first and second bonding materials may be thermoplastic materials with substantially different melting temperatures. The first and the second bonding materials may be thermosetting materials with identical curing temperatures. The first and second bonding materials may be thermosetting materials having different curing temperatures.

In an embodiment, an electrical connector is permanently or semi-permanently assembled to and retained on a mating circuit element in its compressed and actuated state, using a nonconductive adhesive bond between the connector and the circuit element. Subsequently, a second, opposing surface of the electrical connector is permanently or semi-permanently assembled to and retained on a second mating circuit element in its compressed and actuated state, using a non-conductive adhesive bond between the connector second surface and the second mating circuit element and where the adhesive bonding is achievable at a lower temperature than that for attachment to the first circuit element.

In an embodiment, an electrical connector is permanently or semi-permanently assembled to and retained between two opposing, mating circuit elements to form electrical interconnections between them, whereby the attachments to the two mating circuit elements are achieved sequentially and at different bonding temperatures.

In an embodiment, an electrical connector having electrical spring contacts is permanently or semi-permanently assembled to and retained on a mating circuit element in its compressed and actuated state, using an adhesive material disposed between the connector and the circuit element. In one embodiment, the adhesive flows during bonding and partially or fully encapsulates the electrical spring contact of the electrical connector.

In an embodiment, an electrical connector is permanently or semi-permanently assembled to and retained on a mating circuit element in its compressed and actuated state, using an adhesive material disposed between the connector and the circuit element, whereby the adhesive material resides on a first surface of the electrical connector prior to mating the connector to a mating circuit element.

In an embodiment, an electrical connector is permanently or semi-permanently assembled to and retained on a mating circuit element in its compressed and actuated state, using an adhesive material disposed between the connector and the circuit element, whereby the adhesive material has clearance openings for the electrical spring contacts on the connector and for the interconnection terminals on the mating circuit element.

In one embodiment, the adhesive is a thermoplastic polymer. In one embodiment, the adhesive is a thermosetting polymer.

In one embodiment, the adhesive is a pressure sensitive adhesive (PSA).

In one embodiment, the adhesive is a pressure sensitive film or tape with adhesive properties on both surfaces.

In one embodiment, the pressure sensitive adhesive has clearance openings for the electrical spring contacts, and the spring contacts emanate from a first surface of the connector through the openings in the PSA.

In one embodiment, the adhesive is a cyanoacrylate-based adhesive.

In one embodiment, the adhesive is a modified acrylic adhesive.

In one embodiment, the adhesive is a B-staged sheet of modified acrylic adhesive, such as DuPont™ Pyralux® LF or FR Sheet Adhesive.

In one embodiment, the adhesive is a B-staged sheet of modified acrylic adhesive, such as DuPont™ Pyralux® LF or FR Sheet Adhesive, where the sheet adhesive has clearance openings for the electrical spring contacts, and the spring contacts emanate from a first surface of the connector through the openings in the sheet adhesive.

In one embodiment, the adhesive is a B-staged bond ply material comprised of a modified acrylic adhesive, such as DuPont™ Pyralux® LF or FR Bond Ply, where the bond ply has clearance openings for the electrical spring contacts, and the spring contacts emanate from a first surface of the connector through the openings in the sheet adhesive.

In one embodiment, the adhesive is a B-staged sheet adhesive or bond ply comprised of modified acrylic adhesive, such as DuPont™ Pyralux® LF or FR Sheet Adhesive, which is first applied to the connector using a tack lamination process so that the adhesive remains substantially B-staged and is not fully cured until the connector is assembled to the mating circuit element in its compressed and actuated state, and sufficient pressure and/or temperature is applied to bond and fully cure the adhesive to both the connector and the circuit element, thereby holding the conductive spring contacts of the connector in compression against the mating conductive terminals of the mating circuit element to achieve low and stable electrical resistance interconnections. The sheet adhesive or bond ply adhesive has at least one clearance opening through which one or more conductive spring contacts protrude, so that they may compress and form interconnections to the terminals on the circuit element without interference from the adhesive.

In one embodiment, the adhesive is a bond-ply adhesive, which comprises a stabilizing polymer film such as a polyimide film which has disposed on both a first surface and a second opposing surface a sheet adhesive, such as a modified acrylic adhesive.

In one embodiment, the adhesive is DuPont Pyralux® LF or FR Bond-Ply adhesive.

In one embodiment, the bond-ply adhesive has clearance openings for the electrical spring contacts, and the spring contacts emanate from a first surface of the connector through the openings in the bond-ply adhesive, so that they may compress and form interconnections to the terminals on the circuit element without interference from the bond-ply adhesive.

In an embodiment, the integral attaching material is a thermoplastic material which is heated above its melt transition temperature during attachment to the connector, and which is subsequently heated a second time above its melt transition temperature during mating of the connector to a mating circuit element.

In an embodiment, the integral attaching material is a thermoplastic material which is heated above its melt transition temperature during attachment to the connector, and which is subsequently heated a second time above its melt transition temperature during mating of the connector to a mating circuit element, and whereby the connector can be demated with heat applied locally to the connector to re-melt the thermoplastic material and release the connector. In one embodiment, the thickness of the thermoplastic material is sufficient to limit the compression of the electrical spring contacts of the connector to its elastic range during mating, so that it can be de-mated and re-mated multiple times through the application of localized heat without loss of working range of the electrical spring contacts from plastic deformation.

In an embodiment, the integral attaching material is a B-staged thermosetting adhesive that remains somewhat tacky, so that it may be retained on the substrate in accurate alignment until the assembly is complete.

In an embodiment, the connector is a Neoconix PCBeam™ connector, and the integral attaching material is used in place of a coverlay material, with a plurality of openings corresponding to a plurality of surface emanating electrical contact springs, whereby the integral attaching material also functions as a hard compression stop to limit travel of the electrical contact spring of the connector to its elastic range and to prevent plastic deformation and damage to the spring contact. In one embodiment, the integral attaching material is of sufficient thickness to provide a hard compression stop for the electrical contact spring such that the compression force on the contact spring is below its yield strength.

In an embodiment, a normal force connector such as is described in U.S. provisional Patent Application No. 62/163,539, entitled “Low Profile, Normal Force Connector”, and with an application date of May 19, 2015, said connector, also known as an X-Beam™ connector, having a molded body and cantilever beam-like electrical contact springs emanating above one or both of two opposing surfaces, is permanently or semi-permanently assembled to and retained on a mating circuit element in its compressed and actuated state, using an adhesive material disposed between the connector and the circuit element. In an embodiment, the adhesive material is disposed on a first surface of the molded connector body. The teaching of the patent application identified in this paragraph, including its specification and drawings, is incorporated herein by reference.

In an embodiment, the connector comprises a normal force connector, such as a Neoconix PCBeam™ connector or socket or a Neoconix X-Beam™ connector or socket, or a pogo-pin based connector or socket, or another normal force connector or LGA socket, whereby the electrical contact spring elements of the connector are mated to conductive electrical contact terminals or pads on a first surface of a mating circuit element such as an FPC or a PCB by applying a force to the connector body that is normal to a first surface of the mating circuit element, the electrical contact terminals being disposed upon that first surface of the mating circuit element, and the spring contacts are held in compression against the contact terminals using an adhesive disposed on the connector surface between the contact elements. Such contact terminals can be disposed in a pattern, such as a square grid, in a single row or in multiple rows, in a staggered grid, or in other patterns as benefits the particular application. Many electrical sockets, such as test sockets, burn in sockets, or microprocessor sockets, are also normal force connectors, and frequently have pogo pin type or cantilever beam type contact elements, or other normal force (also known as ‘z-force’) electrical spring contact elements that are actuated and form electrical contact to the mating electrical contact terminals on the mating circuit element when a normal force is applied to the socket body. Often this application and maintenance of normal force requires complex and costly tooling including support frames, bolts, lids, and corresponding holes in the mating circuit element to accommodate the affixing means. Such affixing means can be expensive, and also can occupy precious real estate not only on the surface of the mating circuit element, but also on internal layers, such as the interior circuit layers of a PCB or FPC. Other affixing means for normal force connectors include surface mounted clamping mechanisms that are attached with solder or adhesives. These clamping mechanisms require additional real estate on the mating circuit element, and there is a trade off in how much area is occupied by the clamping mechanism attachment to the circuit element, as more area provides for a more robust connection but requires an increase in the size of the circuit element. If the attachment areas for the affixing hardware are limited in area to reduce use of real estate on the mating circuit element, the affixing hardware attachment is subject to failure from shear forces during drop testing and shock and vibration testing of electronic devices, as well during use of products in the field.

In an embodiment of the present invention, an adhesive, disposed on a first surface of a normal force connector, is used in place of mechanical affixing means such as frames, screws, or clamps, to assemble and retain the connector, in an actuated state, with the electrical spring contacts in compression against a mating surface of a circuit element such as an FPC or PCB. The normal force connector in this embodiment has electrical spring contact elements emanating from the first surface of the connector, and the adhesive would be disposed between the electrical spring contacts, but would not be disposed on the electrical spring contacts themselves. In order to mate and retain the normal force connector in its fully compressed state to achieve a low resistance electrical contact with the electrical contact terminals on a mating circuit element, the first surface of the connector would be aligned to, and compressed against, the mating contact terminals on the PCB or FPC. The adhesive material disposed between the contact elements on the first surface of the connector would be treated to form a bond with the surface of the mating circuit element, between the electrical contact terminals. Alternatively, the adhesive material could be disposed on the first surface of the mating circuit element, between the conductive mating terminals, or on both opposing surfaces.

The bonding material used in many embodiments of this invention can be of many different types, depending on the requirements of the application. It can be a thermoplastic material or a thermoset resin such as an epoxy or an acrylic adhesive. It can be a film adhesive or a bond ply adhesive, or can be dispensed or printed or sprayed or otherwise applied as a viscous liquid or paste. In the case of thermosetting adhesives, the adhesive may be applied as a liquid or paste on the connector surface, between the electrical spring contacts, and then partially cured, known as B-staging, so that the adhesive no longer is substantially tacky and no longer flows readily, simplifying handling of the connector. When the connector is to be interconnected to a mating circuit element, the connector is aligned to and compressed against the mating circuit element, and an appropriate temperature and/or pressure cycle is applied to form an adhesive bond between the connector and the mating circuit element and to fully cure the adhesive. Alternatively, a thermoset adhesive or other adhesive can be applied to the mating circuit element, between the contact terminals, rather than to the connector surface.

In one embodiment of the present invention, instantaneous bonding of the connector to a mating circuit element can be achieved by using a pressure sensitive adhesive (PSA), such as a two sided PSA bonding film, sometimes referred to as a double stick tape. In another embodiment, a high strength, two sided PSA film would have release layers on both sides of the film. The PSA film and release layers would have a pattern of openings that match the layout of the electrical spring contacts of the connector, with these openings being of appropriate size and shape to enable free movement of the electrical spring contacts. A first surface of the PSA with pre-cut openings would be disposed on and bonded to a first surface of the electrical connector, following the removal of the release layer from that first surface of the PSA, and the normal force electrical spring contacts emanating from that first surface of the connector would protrude through the respective openings in the PSA layer, with the distal ends of the contacts being a further distance from the first surface of the connector body than the second, outwardly disposed surface of the PSA. Such a connector could then be permanently mounted to a mating circuit element by removing the second release layer from the second, opposing surface of the PSA, aligning the connector to the electrical contact terminals on the mating circuit element, and applying normal force to the electrical connector to compress the electrical spring contacts of the connector against the electrical contact terminals sufficiently to achieve low resistance electrical interconnection, and also sufficient pressure between the PSA second surface and a first surface of the mating circuit element to form a strong adhesive bond. Once the mating pressure is released, the PSA maintains a mechanical bond between the connector and the mating circuit element such that the electrical contact springs would remain in the compressed state and a low resistance electrical interconnection would be formed and maintained. In another embodiment of the present invention, the two surfaces of the PSA have differing adhesive strengths. In an embodiment, a stronger PSA adhesive film is used on the side of the PSA tape attached to the connector, and a lower adhesive strength film is used on the side of the PSA tape to be attached to the mating circuit element. In this way, reworkability of the interconnection may be achievable.

In a further embodiment of the present invention, the openings in a PSA film could be mechanically punched, laser machined, drilled, or otherwise formed, with the opening locations and dimensions designed so as to ensure there is no interference between the PSA film and the interconnections nor with the mechanical movement of the electrical spring contacts during interconnection to the mating circuit element.

In another embodiment of the present invention, a PSA is applied in a pattern to the connector surface or to the surface of a mating circuit element in liquid or paste form, through printing or dispensing or spraying, and is cured to form a tacky, solid PSA film.

In another embodiment, the adhesive is a pressure sensitive adhesive film, which has a differential adhesive strength or ‘tack’ levels on opposing surfaces, and the lower tack level surface being separable and re-bondable to a mating circuit element, to allow repair or rework, while the higher tack level maintains its adhesive bond to the connector, but both tack levels being sufficient to maintain the spring contacts in a fully compressed and actuated state whereby low electrical resistant interconnections are achieved and maintained.

In another embodiment of the present invention, a cyanoacrylate liquid adhesive is applied to the mating surfaces between the connector and the mating circuit element in the interstitial areas between the electrical spring contacts, and forms a near instantaneous bond when the material is compressed to a very thin bond line to retain the connector in the fully actuated configuration to achieve a low resistance and reliable interconnection.

In a preferred embodiment of the present invention, a normal force connector is comprised of an insulating substrate having a first surface and a second opposing surface. A plurality of electrical spring contacts is disposed upon and attached to the first surface of the connector, and emanate outwardly from that first surface. At least one of the spring contacts is isolated from the others of the plurality of contacts on the first surface of the connector. The elastic spring contacts each comprise a base portion attached to the connector insulating body and in electrical contact with a conductive via, and a distal portion extending above the first surface and over a planar portion of the first surface. The conductive via forms an electrical connection between the electrical spring contact on the first surface of the connector and the second opposing surface of the connector. A partially cured adhesive layer, such as a B-staged thermosetting adhesive layer, is disposed over the base portion of the electrical spring contacts and in the areas between the electrical contacts, with clearance openings in the adhesive layer for the distal ends of the electrical spring contacts so as not to interfere with their ability to compress against and form an electrical interconnection with the interconnection terminals on a mating circuit element. The thickness of the adhesive layer is less than the height of the electrical spring contact above the first surface of the connector, to allow sufficient compression distance and force of the electrical spring contact against a mating conductive terminal to create an electrical interconnection with low and stable electrical resistance. The connector can be mated, electrically interconnected and permanently affixed to the mating circuit element by applying sufficient normal force to substantially compress the distal ends of the spring contacts against the electrical contact terminals on the mating circuit element, coupled with the application concurrently or subsequently of sufficient temperature and/or pressure to flow, bond and fully cure the adhesive layer to bond the connector to the mating circuit element in the regions between the distal ends of the electrical spring contacts. In this manner, the first surface of the electrical connector is permanently or semi-permanently mated to the mating circuit element. The second surface of the electrical connector may also comprise a plurality of electrical spring contacts disposed upon and attached to it, and emanating outward from that second surface, where at least one of the plurality of contacts on the second surface is electrically connected to an electrical spring contact on the first surface through the conductive via. In one embodiment, the size of the clearance openings in the adhesive layer are reduced during curing of the adhesive material under compression.

In another embodiment of the present invention, a normal force connector is comprised of an insulating substrate having a first surface and a second opposing surface. A plurality of electrical spring contacts is disposed upon and attached to the first surface of the connector, and emanate outwardly from that first surface to a distance greater than a dimension x. At least one of the spring contacts is isolated from the others of the plurality of contacts on the first surface of the connector. A second plurality of electrical spring contacts is disposed upon and attached to the second surface of the connector insulating substrate, and emanate outwardly from that that surface to a distance greater than a dimension y. The elastic spring contacts on the first and second surfaces each comprise a base portion attached to the connector insulating body and in electrical contact with a conductive via, and a distal portion extending above the first or second surfaces respectively, and over a planar portion of the first or second surface respectively. An adhesive layer, which may be a partially cured (B-staged) thermosetting adhesive layer, or another adhesive type, of a thickness less than x, and preferably of a thickness less than 0.8x, is disposed over the base portion of the contacts and on the first surface of the insulating substrate. The adhesive layer may be a bond-ply adhesive having a central stabilizing film such as polyimide, with both opposing surfaces having a corresponding adhesive layer on it, such as a modified acrylic adhesive. The adhesive layer preferably has openings aligned with the electrical spring contacts and of appropriate size and shape so as to prevent interfere of the adhesive layer with the displacement of the electrical spring contacts during compression, to enable their low resistance interconnection to conductive terminals on a mating circuit element. A coverlay of thickness less than y, and preferably of thickness less than 0.8y, is disposed over the base portion of the second plurality of electrical spring contacts and on the second surface of the insulating substrate, and having clearance openings for the distal ends of the electrical spring contacts. At least one of the electrical spring contacts on the second surface of the connector is electrically interconnected to at least one of the electrical spring contacts on the first surface of the connector. The first surface of the connector can be mated, electrically interconnected and permanently affixed to a mating circuit element by applying sufficient normal force to substantially compress the distal ends of the spring contacts on the first surface of the connector against the electrical contact terminals on the mating circuit element, coupled with sufficient temperature and/or pressure to flow, bond and fully cure the adhesive layer to bond the connector to the mating circuit element in the regions between the distal ends of the electrical spring contacts. The second surface of the connector can be separably mated and electrically interconnected to a second mating circuit element, using mechanical means to retain the connector in position and under compression against the second mating circuit element. In a preferred embodiment, the adhesive layer on the first surface of the electrical connector acts as a hard compression stop, and the thickness of the adhesive layer on the first surface of the electrical connector is sufficient such that when the adhesive makes contact with the surface of the first mating circuit element, the electrical spring contacts on the first surface of the connector remain in their elastic range, and therefore are not plastically deformed. In one preferred embodiment, the adhesive material is a low flow material, such that during curing it retains a high flow viscosity and its thickness does not decrease by more than 50%. In another preferred embodiment, the adhesive material is a bond ply material, whose overall thickness decreases by less than 25% during bonding and curing. In some embodiments of the present invention, distance x is substantially equal to distance y.

Various other options exist for the adhesive layer disposed on the first surface of the insulating substrate of a connector as described in the above embodiments, and in some embodiments disposed over the base portion of a cantilever beam-like electrical spring contact. The adhesive layer may be a bond ply material, such as DuPont Pyralux LF or FR bond ply. These materials consist of a B-staged, acrylic-based adhesive on either side of a polyimide film. The polyimide provides dimensional stability and strength, and the acrylic adhesive provides bonding ability. These materials can be pre-patterned so as to provide a pattern of openings that match the pattern of electrical spring contacts on the electrical connector. The patterned bond ply adhesive can be aligned to and preliminarily bonded to the connector, such that the bond ply overlays the base portions of the contacts while the distal ends protrude through and emanate from the openings in the bond ply adhesive to a distance above the connector's first surface greater than the height of the adhesive above the connector's first surface. The thickness of the adhesive layer can be chosen to optimize performance of the electrical spring contact, such that it is thin enough to allow sufficient compression of the electrical contact spring against a mating conductive terminal to provide an electrical interconnection with low and stable electrical resistance, while being thick enough to prevent over compression of the electrical contact spring, thereby preventing plastic deformation and compression set of the spring. To form the permanent electrical interconnection to a mating circuit element, the connector may be aligned to the mating circuit element contact terminals, normal force applied to compress the spring contacts against the contact terminals, and sufficient temperature and/or pressure is applied to enable the adhesive to flow, wet to the mating surfaces, fully cure and thereby bond the connector to the mating circuit element, thus maintaining the spring contact elements in a sufficiently compressed state where a low resistance electrical connection is maintained.

In another embodiment of the present invention, a bonding material, such as a pressure sensitive adhesive, is disposed onto portions of the surface of one piece of a two piece, mezzanine connector, such as a board to board connector, in which the primary retention mechanism between the mating electrical contacts is laterally induced frictional forces. The adhesive material reduces the probability of an intermittent or extended interruption of the electrical interconnection path through the two halves of the connector, often known as the header and the socket, through separation of the connector header and socket as a result of shock or vibration stresses on the connector, such as might be experienced during testing or field life of a portable electronic device. In a preferred embodiment, the adhesive is a pressure sensitive adhesive film, which has a differential tack levels on opposing surfaces, and the lower tack level surface being separable and re-bondable.

It should be noted that the invention has been described with reference to illustrative embodiments for the purposes of demonstrating the principles and concepts of the invention. The invention, however, is not limited to these examples, as will be understood by persons of skill in the art in view of the description being provided herein. Many modifications may be made to the embodiments described while still achieving the goal of the invention.

Persons of skill in the art will understand that these and other modifications may be made and that all such modifications are within the scope of the invention.

A series of figures is provided to illustrate some, but not all, embodiments of the present invention.

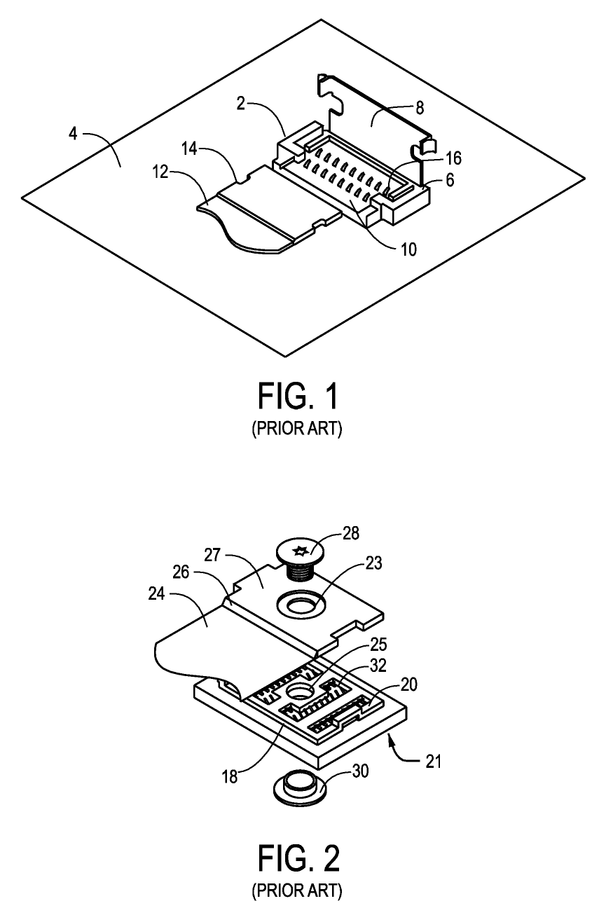

FIG. 1 shows a perspective view of one prior art electrical connector which functions similar to the electrical connectors of the present invention. Electrical connector 2 in FIG. 1 is a normal force, zero insertion force (ZIF) connector, which forms a plurality of electrical interconnections to circuit element 4. Circuit element 4 may be a PCB, an FPC, a semiconductor package substrate, a module, or another type of electrical circuit element. The electrical interconnection between the electrical connector 2 and the circuit element 4 may be achieved by surface mount soldering, by electrically conductive adhesive, or by other means. Electrical connector 2 has a connector housing 6, which may be molded plastic or other suitable material, and which has an outline area substantially larger than the area of the plurality of electrical interconnections being formed. The connector housing 6 has a retention lid, 8, which provides downward or normal force on a mating circuit element 12 when the retention lid 8 is closed and latched. The retention lid 8 may be cam actuated to provide the downward force and latching. Mating circuit element 12 may be a flexible printed circuit, and may have a stiffener 14 attached to a first, upward facing surface of it to aid in the application of uniform force from the connector lid through the mating circuit element to the plurality of electrical spring contacts, 16, disposed on a first upward facing surface of a connector substrate 10. The connector substrate 10 may be integral with the connector housing 6, such that they are a unitary element, or the connector substrate 10 may be an independent element which is inserted into and retained within the connector housing 6. The electrical connector 2 shown in FIG. 1 illustrates some of the drawbacks of some of the prior art electrical connectors. The surface area that the electrical connector 2 occupies on the circuit element 4 is substantially larger than the actual area of the plurality of electrical interconnections formed, increasing the surface area of circuit element 4 required for the interconnection, and therefore potentially increasing its required overall size, and therefore its cost, while inhibiting miniaturization of the electronic device of which it is a part. Cam actuated connector lids for ZIF connectors are known to have retention issues, whereby the lid can open intermittently due to forces generated by shock or vibration. Additionally, the connector housing materials and fabrication add cost and weight to the assembly.

FIG. 2 shows a perspective view of another prior art electrical connector assembly. Electrical connector 18 is a surface mount connector having a first downward-facing surface 21. Proximal ends (not visible in this drawing) of a plurality of electrical spring contacts 32 are electrically interconnected via solder joints (not shown) to electrical connection terminals on circuit element 22, which may be a PCB. The distal ends of electrical spring contacts 32 emanate upward and away from the mating circuit element 22 such that they are above a second, opposing and upward-facing surface 20 of connector 18. The distal ends of electrical spring contacts 32 are electrically interconnected to the proximal ends of the electrical spring contacts. The distal ends of electrical spring contacts 32 are electrically interconnected separably to electrical connection terminals on the circuit element 24, which may be an FPC. The circuit element 24 includes an optional stiffener 27 mounted on it using adhesive 26, so that uniform normal force may be applied by a screw 28 and a nut 30 to compress connection terminals on circuit element 24 against the distal ends of electrical contact springs 32. The electrical connector assembly shown in FIG. 2 requires large through holes 23, 25 in circuit element 24 and in the electrical connector 18 in order to accommodate the screw 28 that applies a normal compression force to actuate and retain the electrical connector 18 on circuit element 24 to form low resistance interconnections between electrical spring contacts 32 on the electrical connector 18 and connection terminals on circuit element 24. This type of electrical connector also requires manual or semi-manual assembly, or highly expensive automation for its assembly process.

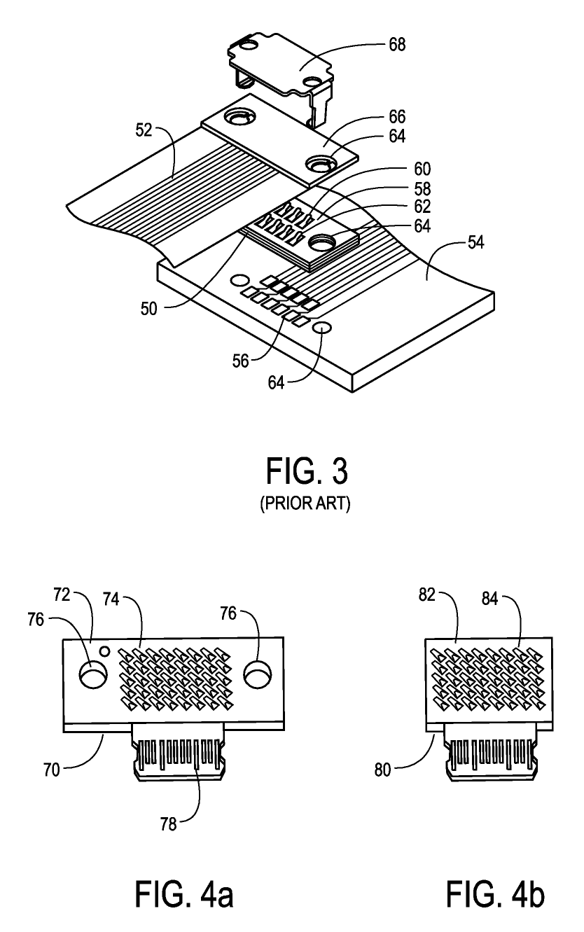

FIG. 3 shows a perspective view of another prior art electrical connector. Electrical connector 50 may be a Neoconix PCBeam™ connector, or another type of normal force connector having a plurality of electrical spring contacts 60 emanating from a first surface 58. The electrical connector 50 is utilized to form electrical interconnections between circuit terminals 56 on circuit element 54 and circuit terminals (not shown) on a circuit element 52. The second, opposing surface of connector 50 (not shown) may be electrically interconnected to circuit connection terminals 56 on circuit element 54 using surface mount soldering, conductive adhesive, or through compression of opposing elastic spring contact elements against circuit terminals 56. Circuit element 54 may be a rigid PCB or other circuit element. The circuit element 52 may be a flexible printed circuit, and may have a stiffener 66 mounted on it above and opposite the circuit terminals. A spring clip 68 may be used to align, compress, and retain connector 50 between circuit elements 54 and 52. This spring clip 68 requires two through holes in each of circuit elements 54 and 52 as well as in connector 50, occupying substantial real estate on all layers of these circuit elements which therefore cannot be used for other wiring or interconnection purposes. A spring clip 68 is one type of mechanical clamp used to provide a normal force on a plurality of spring contacts in the prior art.

FIG. 4 (comprising FIG. 4A and FIG. 4b) is a drawing comparing a prior art electrical connector, shown in FIG. 4a, and an electrical connector of the present invention, shown in FIG. 4b. Electrical connectors 70 and 80 in FIGS. 4a and 4b, respectively, are what are sometimes referred to as “normal force connectors”, forming electrical connections between their respective arrays of electrical spring contacts 74 and 84 and mating circuit terminals 78, 88 on mating circuit elements through application of force normal to the surface of the mating circuit elements, thereby compressing the contact springs 74 and 84, respectively. The electrical connector 70 shown in FIG. 4a is compressed and retained by mechanical means (sometimes called a “clamp” or clamping member), such as screws and nuts as shown in FIG. 2, or spring clips as illustrated in FIG. 3. The area of the electrical connector 70 as shown in FIG. 4a, and the real estate it occupies on a mating circuit element, is substantially larger than the area of the electrical connector 80 as shown in FIG. 4b for an equivalent number of electrical interconnections. The electrical connector 70 of FIG. 4a also requires large through holes 76 in the mating circuit elements in order to compress and retain the assembly in an actuated state. Mating surface 72 of connector 70 is a rigid insulator material, such as liquid crystal polymer (LCP), polyimide, or other non-adhesive polymer.

The electrical connector 80 shown in FIG. 4b requires no extraneous hardware (such as a clamp) or tooling holes to retain and compress it against a mating circuit element. A bonding material 82 is disposed upon the mating surface of connector 80, between but not over the elastic, distal ends of electrical contacts 84. When the mating surface of connector 80 is aligned to and compressed against circuit terminals on a mating circuit element, the bonding material is treated (or activated) so as to form a permanent or semi-permanent bond to the mating circuit element, maintaining the connector in a fully actuated state with the springs sufficiently compressed against conductive circuit terminals on the mating circuit element to form low resistance electrical contacts to the circuit terminals. The connectors shown in FIG. 4A and FIG. 4b may be, for the purpose of example, USB connectors, whereby tab 78 has USB standard electrical interconnection terminals.

An array of electrical spring contacts 74 of the electrical connector 70 are variously electrically interconnected to various USB terminals on USB connector tab 78. The array of electrical spring contacts 74 on the electrical connector 70 forms the interconnection between the USB connector 78 and a main logic board or mother board in an electronic device such as a laptop computer or mobile phone. The electrical connector 80 of the present invention provides the same interconnection between a device's main logic board and a USB connector or port while utilizing much less area on the main logic board, and requires no extraneous tooling, simplifying assembly and reducing manufacturing (assembly) cost.

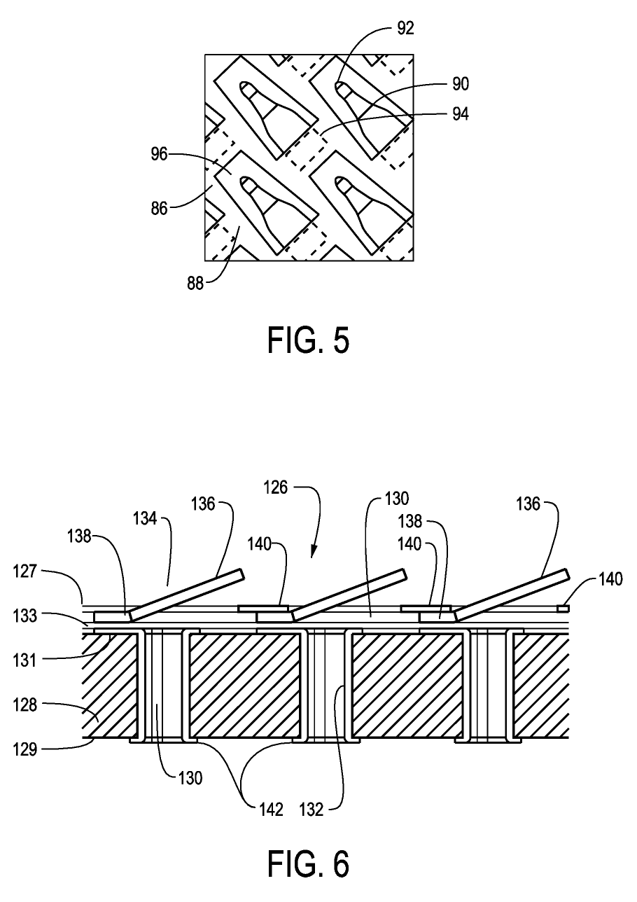

FIG. 5 shows a drawing of an expanded view of a portion of an electrical connector of the type shown in FIG. 4b. A plurality of electrical spring contact elements 90 are disposed on a first surface of a connector body 86. Contact elements 90 comprise a proximal end, or base end, 94 (hidden under a sheet of bonding material 88) and a distal end 92. Proximal end 94 is attached to the first surface of connector body 86, and distal end 92 emanates from that first surface. A sheet of bonding material 88 is disposed upon the first surface of a connector body 86, and overlies the proximal ends of electrical spring contact elements 90. Electrical spring contact elements 90 resemble cantilever elastic beams, and may be comprised of a high strength, high conductivity spring material such as copper-beryllium alloy, phosphor-bronze, copper-nickel-tin alloys, or other conductive spring materials. The sheet of bonding material 88 has a plurality of openings 96 substantially aligned with the plurality of distal ends 92 of the spring contact elements 90, and through which the distal ends 92 emanate to a distance above the first surface of the connector body 86 greater than the thickness of the sheet of bonding material 88. The openings 96 in the sheet of bonding material 88 are designed so that the sheet of bonding material 88 will not interfere with the displacement of the electrical spring contact elements 90 during compression. The sheet of bonding material 88 may be a polymeric material with adhesive properties, such as a thermoplastic polymer, or a thermosetting polymer. In one embodiment, the sheet of bonding material 88 includes a modified acrylic adhesive. In another embodiment, the sheet of bonding material 88 carries an epoxy material.

Adhesive may carried on a sheet of bonding material, and openings 96 may be pre-formed in the bonding material prior to its attachment to the first surface of connector body 86. The adhesive carried on the sheet of bonding material 88 may be a B-staged, or partially cured, thermosetting adhesive. It may also be a heterogeneous material, such as a bond-ply material, comprising an adhesive layer on either side of a stabilizing film or sheet, such as a polyimide film or a metal sheet. The film or sheet may provide mechanical and dimensional stability to the adhesive layers. The openings 96 may be created by mechanical punching, laser ablation, mechanical drilling, plasma etching, or by other means as may be known to one skilled in the art. The thickness of the sheet carrying the bonding material 88 may be chosen to limit the total displacement of the electrical spring contact elements 90 to a predominately elastic range, where little or no plastic deformation of the spring contact occurs upon full compression to a level coplanar with the surface of bonding material 88. As such, bonding material 88 may act as a hard compression stop. The sheet of bonding material 88 may be used to bond the connector body 86 to a mating circuit element, in a state where electrical spring contact elements 90 are in alignment with, and compressed against, mating interconnection terminals on the mating circuit element. In the case of a thermoplastic bonding material, the connector body 86 would be aligned to and compressed against a mating circuit element, and then pressure and/or sufficient temperature would be applied to melt the thermoplastic and allow it to form intimate contact with the mating circuit element, at which point it would be cooled in order to form a semi-permanent bond to the mating circuit element. In this manner, the bonding material would maintain the connector in a compressed and actuated state against the mating circuit element such that its electrical spring contacts form low resistance electrical interconnections to interconnection terminals on the mating circuit element. In another embodiment, the bonding material may be a B-staged, thermosetting adhesive material, and the bond to a mating circuit element may be formed by the application of normal force and elevation of temperature to cause the adhesive to liquefy, flow and cure.

FIG. 6 shows a drawing of a cross sectional view of a connector of the present invention, such as the connector shown in FIGS. 4b and 5. Connector 126 comprises a connector body 128, through which side to side interconnection means 130, such as plated through holes with plated metal 132, provide electrical interconnection between a top surface 127 of the connector and a bottom, opposing surface 129. A plurality of electrical spring contacts 134 reside on first surface 127 of connector 126, and comprise a proximal end 138 and a distal end 136 which together form a unitary body. In one embodiment, contacts 134 are comprised of a high strength spring material with elongated grains substantially oriented in the direction of the length of the beam. In another embodiment, the high strength spring material is heat treated to increase its hardness and strength. Proximal ends 138 of electrical spring contacts 134 are attached to, and electrically interconnected with conductive terminals 131 on an upper surface 133 of the connector support body 128. The electrical interconnection may be achieved with solder, or plating, or by other means. Conductive terminals 131 on first surface 133 of connector substrate 128 are electrically interconnected to respective terminals 142 on bottom surface 129 of connector body 128 by interconnection means 130, which may be plated through holes. Connector body 128 is an insulative dielectric material, which may be an FR4 PCB material or other polymer or composite insulating material. Disposed on first surface 127 and over the proximal ends 138 of spring contacts 134 is a bonding material, such as a polymer with adhesive properties, which is patterned with a plurality of openings 130 which substantially align with the distal ends 136 of spring contacts 134 and which allow free displacement of the distal ends 136 of spring contacts 134 through compression and decompression cycles without interference. The thickness of bonding material 140 may be chosen to limit the total displacement of the electrical spring contact elements 134 to a predominately elastic range, where little or no plastic deformation of the spring contact occurs upon full compression to the surface of bonding material 140. As such, bonding material 140 may act as a hard compression stop. Bonding material 140 may be used to bond first surface 127 of connector 126 to a mating circuit element, with distal ends 136 of electrical spring contact elements 134 in alignment with, and compressed against conductive mating interconnection terminals on the mating circuit element. Bonding material 140 may thereby be used to retain connector 126 in a full compressed state against a mating circuit element, by forming an adhesive bond to the mating surface of the mating circuit element, to maintain low resistance electrical interconnections between the spring contacts and mating circuit interconnection terminals without the requirement for extraneous mechanical attachment means, such as screws or clamps or other hardware. Conductive terminals 142 on second surface 129 of connector 126 may be attached and electrically interconnected to mating circuit terminals on a second mating circuit element, such as by soldering, such that connector 126 forms a plurality of electrical interconnections between the first and second mating circuit elements.

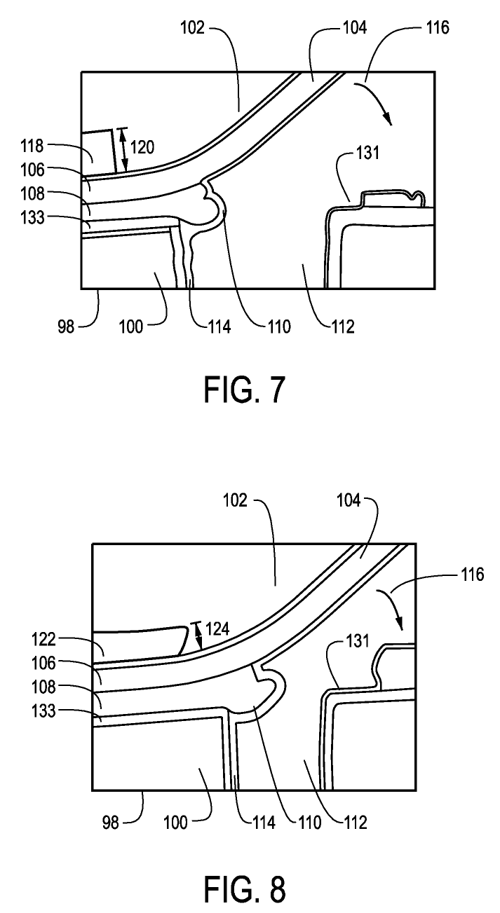

FIG. 7 shows a drawing of a magnified view of a portion of a connector 98 of the present invention, including a portion of an electrical spring contact 102 comprised of a distal end 104 emanating upward from a first surface 131 of connector substrate 100, and a proximal end 106 attached to connector substrate 100 with an attachment material 108, such as a bond ply adhesive or a solder. Proximal end 106 of electrical spring contact 102 may be electrically interconnected to a circuit terminal 133 on connector substrate 100. Circuit terminal 133 on the first surface 131 of connector body 199 is itself interconnected to plated through hole 112 having plating 114, and by which electrical interconnection is formed between first surface 131 and a second, opposing surface (not shown) of connector body 100. A bonding material 118, such as an adhesive material, is disposed upon the first surface 131 of the connector 98, and overlies the proximal end 106 of electrical spring contact 102 while having clearance openings for the distal ends 104 of contacts 102. When distal end 104 of contact 102 is compressed against a mating circuit terminal (not shown) on a mating circuit element (also not shown in this FIG. 7), in a general downward direction as illustrated by directional arrow 116, bonding material 118 will make contact to the mating surface of the mating circuit element, and can be permanently or semi-permanently affixed to that surface through formation of an adhesive bond. In one embodiment, the bonding material 118 is a thermosetting polymer, and the application of pressure and/or elevated temperature may accelerate the bonding process. In another embodiment, the bonding material 118 is a pressure sensitive adhesive (PSA), and the bonding may effectively be achieved instantaneously upon contact with the mating surface of a mating circuit element. In another embodiment, the bonding material 118 is a thermoplastic polymer having adhesive properties, and a melting and re-solidification cycle may be required to form a bond with the mating surface of a mating circuit element, necessitating a thermal cycle of heating followed by a cooling cycle. Thickness 120 of bonding material 118 may be chosen to limit the downward, compressive displacement of electrical spring contact 102 during interconnection to a mating circuit element. Bonding material 118 may be a homogeneous material, such as a sheet adhesive comprised of a modified acrylic. It may also be a bond ply material, such as a polyimide film coated on each opposing surface with a modified acrylic adhesive. Such bond ply material may be of the type manufactured and marketed by DuPont and known as Pyralux™ Bond Ply material, such as Pyralux LF or a flame retardant version sold under the trademark Pyralux FR. In one embodiment, a bond ply with a polyimide film of 0.001″ thickness may have a 0.0005″ thick coating of a B-staged, modified acrylic on each side. In another embodiment, the modified acrylic coatings may be 0.001″ thick. In another embodiment, the polyimide film may be 0.002″ thick, and the modified acrylic films may be 0.0005″ or 0.001″ in thickness. In one embodiment, the bonding material 118 (the B-staged bond ply material) is first patterned with a plurality of openings corresponding to and substantially aligned with the positions of electrical contact springs on the first surface of an electrical connector. In this embodiment, the bonding material 118 may then be attached to the connector first surface such that it is retained on the first surface, but it remains substantially B-staged, such that it is not fully cured. Such an attaching process may be commonly known as a partial lamination or a tack lamination process. Subsequently, when the connector's first surface 131 is mated to a mating circuit element, sufficient heat and/or pressure may be applied for a sufficient duration of time such that the adhesive flows, fully cures, and forms a bond between the connector and the mating circuit element, so as to retain the connector in its mated configuration on the mating circuit element.

FIG. 8 shows a drawing of a magnified view of a portion of the connector 98 of the present invention, similar to that shown in FIG. 7. In FIG. 8, bonding material 122 has a thickness 124 which is less than the thickness 120 of the bonding material 118 of the connector 98 shown in FIG. 7. The bonding material 122 in FIG. 8 will allow the distal end 104 of elastic contact 102 to be compressed to a position closer to the first surface 131 of the connector 98 than the bonding material 118 in FIG. 7 will allow. The thickness 124 of the bonding material 122 may be chosen depending, in part, on the design of the electrical spring contact 102 including its total elastic range. In general, a thinner bonding material may be chosen for an electrical spring contact 102 with a greater elastic range. Bonding material thickness 122 may also be dependent upon the rigidity and compressive modulus of the bonding material 118. A bonding material 118 with a lower compressive modulus may need to be thicker in order to limit displacement of a particular electrical spring contact 102 to its elastic range.

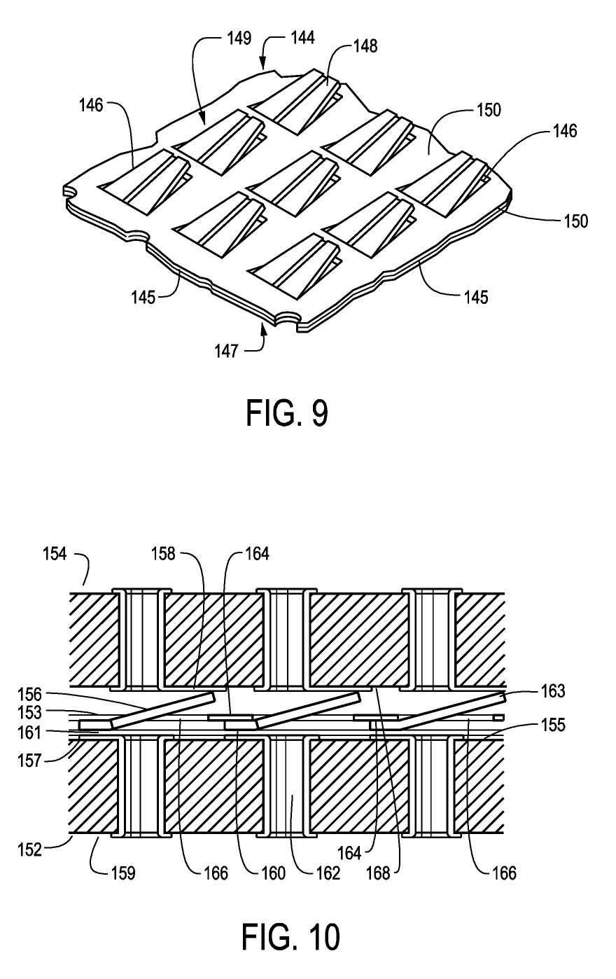

FIG. 9 shows a drawing of a perspective view of a portion of a connector 144 which may be illustrative of the connector shown in FIG. 6, connector 144 having a first surface 145 upon which are disposed a plurality of elastic, electrical spring contact elements 149, and a second, opposing surface 147. Electrical spring contacts 149 have distal ends 148 and proximal ends (not visible in this view). Bonding material 150 is disposed on the first surface 145 of the connector 144 and overlies proximal ends, or bases (not visible in this drawing but analogous to proximal ends 138 in FIG. 6) of electrical spring contacts 148. The bonding material 150 has a plurality of openings 146 substantially aligned with contacts 148 so as to allow the contacts to move freely without interference by the bonding material 150. The bonding material 150 may be an adhesive material, such as a modified acrylic adhesive, an epoxy material, a pressure sensitive adhesive, or other bonding materials with adhesive properties. The nature of bonding material 150 is selected such that it forms a strong adhesive bond to a mating circuit element, sufficient to bond and retain the first surface 145 of the connector 144 to the mating surface of a mating circuit element. In a preferred embodiment, the bonding material 150 is a low-flow material, such that during curing it retains a relatively high viscosity and does not substantially reduce the size of the plurality of openings 146. In one embodiment, the bonding material 150 is a bond-ply material consisting of two layers of a modified acrylic adhesive, one on either opposing surface of a film of a polyimide material, and the plurality of openings 146 are present in all three layers of the bond ply material. In another embodiment, the flow of bonding material 150 into the plurality of openings 146 during adhesive curing is less than 0.005 inches per 0.001 inch of adhesive thickness.

FIG. 10 is a drawing showing a cross sectional view of a connector 152 of the type shown in FIG. 6 aligned with, and making initial contact to, a mating circuit element 154, but prior to full mating. The connector 152 has a plurality of electrical spring contacts 156 disposed on a first surface 155 of the connector 152, each electrical spring contact 156 being a unitary body comprising a distal end 163 emanating outward from the first surface 155 of the connector 152, and a proximal end 160 attached to the first surface 155 mechanically by an attachment material 161. The electronic spring contacts 156 are electrically connected to conductive terminals 157 on the first surface 155. Such electrical connection may be accomplished by attachment material 161, which may be a conductive solder, or another fusible metal or metal alloy, or may be a conductive adhesive or other electrical interconnection material. Alternatively, attachment material 161 may be a non-conductive bonding material, and electrical interconnection between the electronic spring contacts 156 and the conductive terminals 157 may be accomplished by other means, such as metal plating. The conductive terminals 157 are electrically connected to a second surface 159 of connector 152 by plated through holes 162. A mating circuit element 154 has electrical interconnection terminals 158 disposed on a first surface 168, with the electrical interconnecting terminals 158 respectively aligned with distal ends 163 of electrical spring contacts 156 of the connector 152. A force normal to the first surface 155 and first mating circuit element surface 168 is applied so that distal ends 163 of the electrical spring contacts 156 are compressed against the mating electrical interconnection terminals 158 of the mating circuit element 154. FIG. 10 shows incomplete mating of the connector 152 and the mating circuit element 154, such that the electrical spring contacts 156 are not fully compressed and the first surface 155 of the connector 152 has not made contact with the first surface 168 of the mating circuit element 154. In practice, the electrical spring contacts 156 are typically fully or substantially compressed by application of normal force until the first surface 155 of the connector 152 makes contact with the first surface 168 of the mating circuit element 154. Once contact occurs, bonding material 164, disposed on the first connector surface 153 of the connector 152 and overlying proximal ends 160 of the electrical spring contacts 156, is treated so as to bond fully to the first surface 168 of the mating circuit element 154 and to first surface 155 of connector 152, and thereby retains the connector in a mated and fully compressed configuration without the need for extraneous hardware to clamp or retain connector 152 against the mating circuit element 154. The bonding material 164 has openings 166 substantially aligned with the distal ends 163 of the electrical spring contact elements 156, and allowing full compression of the contact distal ends 163 without direct interference from bonding material 164. The bonding material 164 may be a polymer. It may be a thermosetting adhesive, such as an epoxy or modified acrylic. It may be a thermoplastic material. It may be a pressure sensitive adhesive. It may instead be a bond ply material, if desired. The bonding material 164 may be a pre-patterned film or bond ply material. Alternatively, it may be applied as a paste or liquid in a pattern process such as printing, spraying, or dispensing, so as to coat only the interstitial areas between the distal ends of the electrical spring contacts 156. In an alternative embodiment, the bonding material 164 may reside on the mating circuit element 154, rather than on the connector 152, prior to mating. The bonding material 164 may require a curing cycle, such as the application of temperature, or of temperature and pressure, to form a sufficient bond so as to retain low resistance interconnections between the electrical spring contacts 156 of the connector 152 and the circuit interconnection terminals 158 of the mating circuit element 154. Alternatively, bonding material 164 may form a nearly instantaneous bond between the first surface 155 of the connector 152 and the first surface 168 of the mating circuit element 154, such as may be achieved with a pressure sensitive adhesive or with a cyanoacrylate adhesive. In an alternative embodiment, the bonding material 164 may reside on the first surface 155 of the connector 152 in the interstitial areas between electrical spring contacts 156 but not overlying the proximal ends 160 of the electrical spring contacts 156. While the electrical spring contacts 156 illustrated in FIG. 10 are shown as cantilever-beam type spring contacts, they may also be comprise alternative spring contact geometries, such as coil springs, or pogo pins, or s-shaped springs, or other normal force electrical spring contact geometries such as one skilled in the art might seek to utilize.

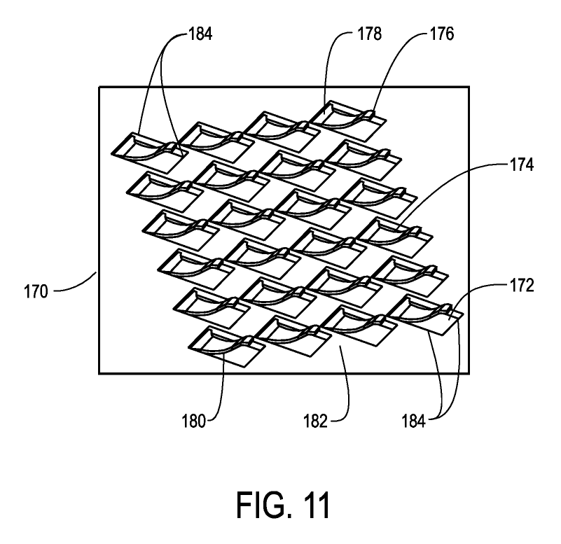

FIG. 11 shows a drawing of a perspective view of a portion of a connector 170 of the present invention. The connector 170 consists of a plurality of electrical spring contacts 174 which are shown in a rectangular array configuration, although other configurations such as rows may also be used, and disposed on a first surface 172 of the connector 170. The connector 170 has plated vias 180 which form electrical interconnections from the first surface 172 to a second, opposing surface (not visible in this figure). The electrical spring contacts 174 are electrically interconnected to the vias 180 through which they are electrically connected to terminals on the opposing second surface. The electrical spring contacts 174 each have a proximal end 178 which is attached to first surface 172 and a distal end 176 which emanates outwardly from the first surface 172 to form a three dimensional electrical contact spring. Bonding material 182 is disposed on the first surface 172 of the connector 170, and has a plurality of openings 184, each substantially aligned with a respective one of the plurality of the electrical spring contacts 174, and enabling distal ends 176 of the electrical spring contacts 174 to be substantially compressed, by application of normal force, downward and into the opening 184 through the bonding material 182 without contacting the bonding material 182. In a preferred embodiment, the thickness of the bonding material 182 is chosen such that it creates a hard compression stop that limits the displacement of the distal ends 176 of the electrical spring contacts 174 so as to limit stress on the electrical spring contacts 174 and prevent stress cracking or excessive plastic deformation or other degradation of the electrical spring contacts 174.

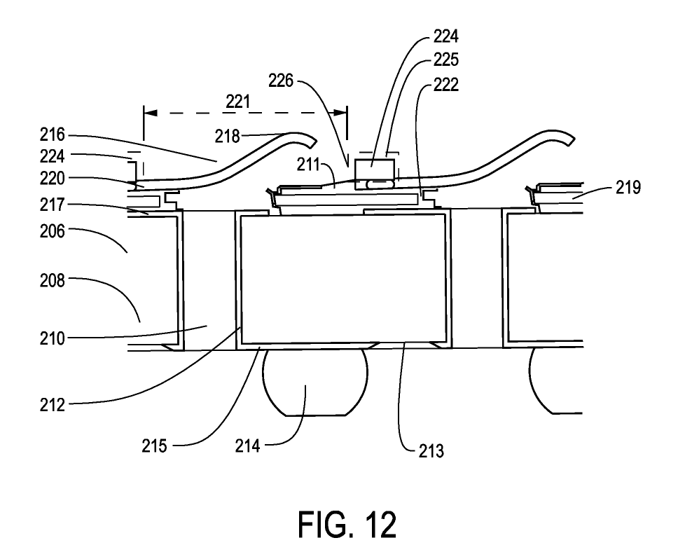

FIG. 12 shows an optical micrograph of a cross section of an embodiment of the present invention. A connector 206 comprises a connector body 208, which is an insulating substrate. The connector body 208 may be a printed circuit board material such as FR4 or it may be another insulating dielectric material. The connector body 208 has plated through holes 210 with plating 212 that form electrical interconnections from a first surface 211 to a second surface 213. The plated through holes 210 electrically connect conductive terminals 217 on the first surface 211 of the connector body 208 to conductive terminals 215 on second surface 213 of connector body 208. Electrical spring contacts 216 are disposed on the first surface 211 of the connector body 208, and are mechanically attached with an attachment material 219, which may be an adhesive material, such as a bond-ply material. The electrical spring contacts 216 are interconnected to the conductive terminals 217 by plated metal 222 which bridges across the attachment material 219. Alternatively, the attachment material 219 may be an electrically conductive attachment material, such as a conductive adhesive or a solder material. Solder balls 214 are reflowed onto the conductive terminals 215 of the second surface 213. Bonding material 224 resides on portions of the first surface 211 of the connector body 208, and overlie proximal ends 220 of contacts 216. Bonding material 224 is highlighted by illustrative dashed lines 226 so that it is more easily observed in this micrograph. Bonding material 224 has openings 221, illustrated by hashed arrow 221. Openings 221 allow the distal ends 218 of spring contacts 216 to be fully compressed into the openings 221 of bonding material 224. Bonding material 224 is bonded to a mating circuit element (not shown) when sufficient normal force to compress distal ends 218 of electrical spring contacts 216 to a level approximately coplanar with first surface 225 of bonding material 224, and appropriate bonding parameters such as temperature and/or pressure are applied, forming a permanent or semi-permanent interconnection between connector 206 and a mating circuit element. Solder balls 214 are used to interconnect the opposing surface of connector 206 to another circuit element.

In one embodiment, second surface 213 of connector 206 may be mounted on a second circuit element which may be, for example, a flexible printed circuit, or a rigid printed circuit board, using surface mount attachment methods to reflow the solder bumps 214 onto electrical connection terminals on the flexible printed circuit or rigid PCB. Subsequently, first surface 211 of connector 206 may be aligned to and compressed against a first mating circuit element, such as a rigid printed circuit board, with distal ends 218 of electrical spring contacts 216 aligned to and in electrical contact with electrical connection terminals on the PCB. First surface 225 of bonding material 224 would then be bonded to the mating surface of the PCB in the regions between distal ends 218 of electrical spring contacts 216.

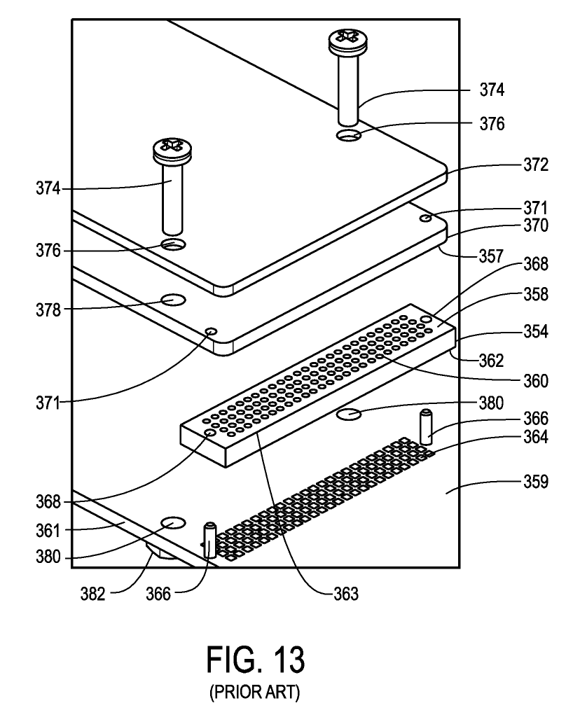

FIG. 13 shows a drawing of a perspective view of a prior art connector and associated mounting hardware. Connector 354 is a normal force connector, such as a dual beam PCBeam™ connector, having a first surface 358 and a second, opposing surface 362, and is utilized to interconnect mating circuit element 370 and second mating circuit element 361. A plurality of electrical spring contact elements 360 are disposed on first surface 358, and interconnected electrically to respective electrical spring contacts on second surface 362. A coverlay material 363, such as a polyimide film, is disposed on and adhesively bonded to first surface 358 of connector 354, with openings for electrical spring contacts 360. The coverlay material may act as a hard compression stop to prevent excessive displacement of spring contacts 360. Electrical connector 354 has tooling alignment holes 368, which correspond to tooling pins on mating circuit element 361 and tooling alignment holes 371 on mating circuit element 370. Mating circuit elements 361 and 370 also have, respectively, screw holes 380 and 378, to enable actuation and clamping of connector 354 between mating circuit elements 361 and 370. Stiffener 372 is used to apply uniform force across the full area of connector 354 during clamping. Electrical spring contacts on second surface 362 of connector 354 mate electrically to corresponding electrical connection terminals 364 on a first side 359 of circuit element 361. Electrical spring contacts 360 on first side 358 of electrical connector 354 mate to corresponding electrical connection terminals on a first side 357 of mating circuit element 370. Alignment pins 366 are used to align circuit element 361 to connector 35 and mating circuit element 370. Screws 374 and nuts 382 are used to mate and compress connector 354 between mating circuit elements 361 and 370. Substantial area on multiple circuit layers of circuit elements 359 and 370 is occupied by tooling and screw holes and associated keep-out areas, adding to size of the interconnection. Additionally, the extraneous clamping and alignment hardware adds cost to the interconnection.

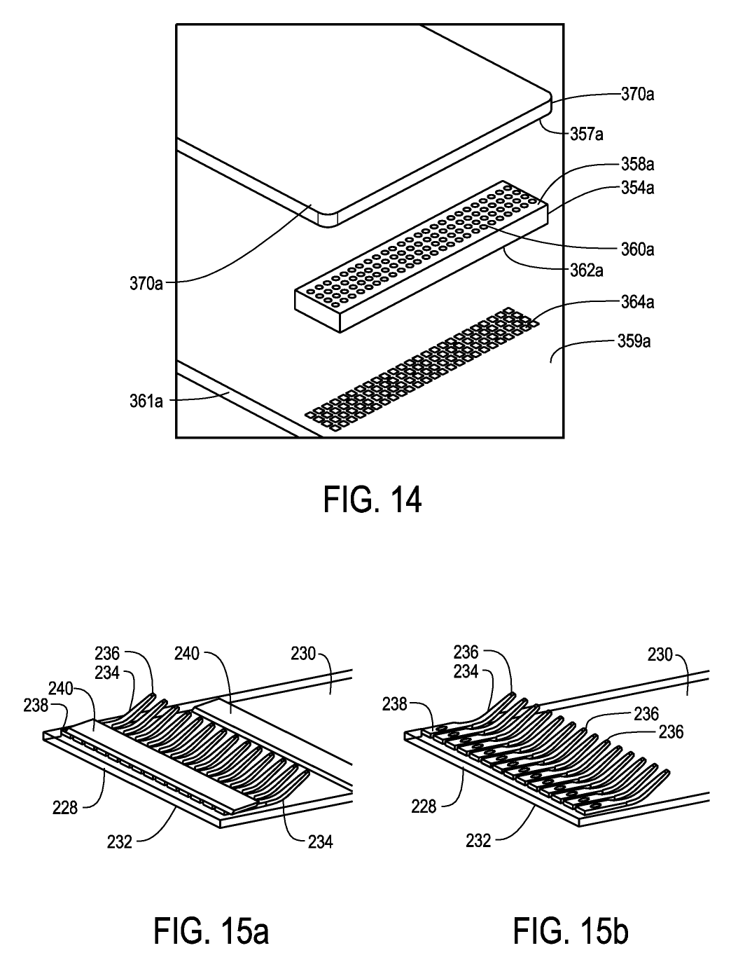

FIG. 14 shows a drawing of a perspective view of a connector 354a of the present invention, having advantages over prior art connector 354 shown in FIG. 13. Connector 354a utilizes a bonding material on first surface 358a and on second surface 362a, in place of a coverlay material, to interconnect and retain connector 354a in a compressed and actuated configuration between circuit elements 361a and 370a. Connector 354a is aligned to circuit elements 359a and 370a, using optical alignment means or temporary tooling, and normal and opposing force is applied between circuit elements 370a and 359a so as to mate to connector 354a. Appropriate bonding conditions are applied to the assembly in order for the bonding materials on opposing surfaces 358a and 362a of connector 354a to form a bond to mating circuit elements 370 and 359a. In this manner, the connector in FIG. 14 is permanently mated to circuit elements 370a and 359a through adhesive bonding, and forms a low resistance and stable electrical interconnection between them without the requirement for the extra real estate in connector 358a and in mating circuit elements 370a and 359a for tooling holes and clamping. Connector 354a also eliminates the requirement for screws, nuts, and stiffener plates, thereby reducing not only the area occupied by the interconnection but also the bill of materials, thus enabling both miniaturization and cost reduction for the interconnection. In an embodiment of the present invention, the bonding material on first surface 358a is of a different composition than the bonding material on second surface 362a, whereby the bonding and curing conditions are substantially different for the two materials. In an embodiment, the bonding material on second surface 362a of connector 354a has a much lower bonding and curing temperature than the bonding material on first surface 358a. Second surface 362a of connector 354a is mated with and bonded to circuit element 359a, and fully cured, whereas the adhesive on first surface 358a remains at a B-staged cure state. Subsequently, first surface 358a of connector 354a is mated with and bonded to circuit element 370a, whereupon the bonding material on first surface 358a is then fully cured.

FIG. 15 shows a drawing of a perspective view of an interconnection element 228 of the present invention. Interconnection element 228 has a plurality of electrical spring contacts 234 disposed on a first surface 230. Contacts 234 in FIG. 15 are arranged in a linear row, but one skilled in the art could contemplate other configurations, such as multiple linear rows of contacts, or an area grid of contacts. Interconnection element 228 may be comprised of a flexible printed circuit substrate, and the elastic spring contacts 234 may be integral to the flexible printed circuit substrate, being mechanically attached and electrically interconnected to conductive circuit traces on the flexible printed circuit substrate. Electrical spring contacts 234 in FIG. 15 are approximately shaped as a three dimensional cantilever beam, with a proximal end 238 attached to first surface 230 of interconnection element 228 and a distal end 236 emanating out of the plane of first surface 230. The drawing in FIG. 15a shows bonding material 240 which has been disposed on a portion of first surface 230, and which overlies proximal ends 238 of contacts 234 and the area between the proximal ends, as well as portions of first surface 230 of interconnection element 228. Bonding material 240 has one or more openings through which distal ends 236 of electrical contacts 234 emanate, and which allow distal ends 236 to be compressed without interference. In FIG. 15a, electrical spring contacts 234 are shown as a linear row of contacts on a very tight pitch, whereby a single opening for the row of contacts is more practical than a discrete opening for each contact. Bonding material 240 has adhesive properties, and is capable of being bonded to a mating circuit element to hold interconnection element 228 in compression against the mating circuit element on an ongoing basis and with sufficient bond strength to provide low resistance electrical interconnections between electrical spring contacts 234 and interconnection terminals on the mating circuit element. The drawing of FIG. 14B shows a view of the interconnection element 228 prior to application of the bonding material to first surface 230 and proximal contact ends 238.

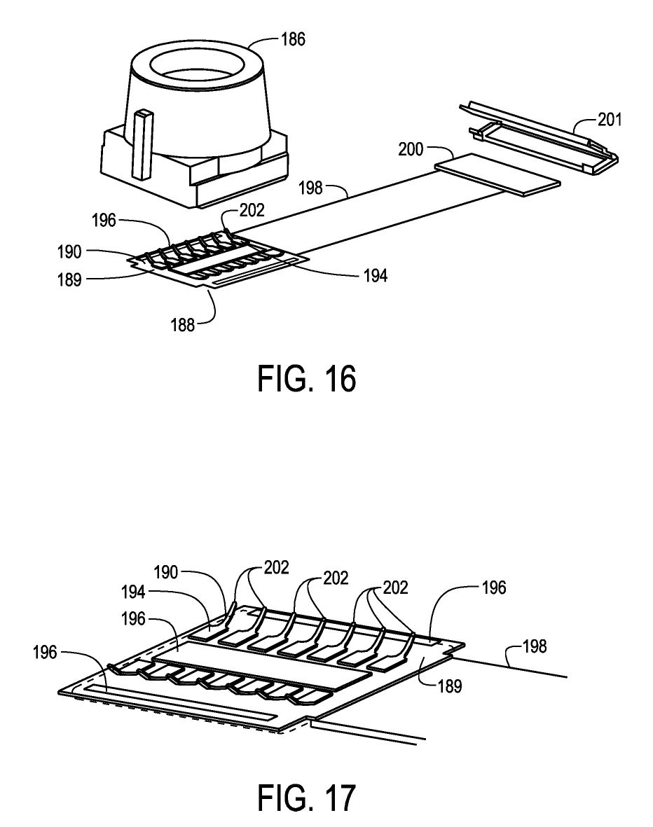

FIG. 16 shows a perspective drawing of a connector 188 of the present invention, used to form electrical interconnections to a module 186, such as a camera module or a sensor module for a mobile electronic device such as a mobile phone. Connector 188 has been electrically and mechanically interconnected, such as by surface mount soldering or electrically conductive adhesive, to printed circuit substrate 198, which may be a flexible printed circuit or a rigid printed circuit. Connector 188 has a first surface 189 upon which are disposed electrical spring contact elements 190, with proximal ends 194 attached to first surface 189 and distal ends 202 emanating away from and above first surface 189. Spring contact elements 190 are designed to form low resistance electrical interconnections to interconnection terminals on a mating module circuit element when a normal force is used to compress the connector against the mating module. For example, connector 188 may electrically interconnect module 186 to circuit element 198, which may be a flexible printed circuit, and the other end 200 of which is in turn electrically interconnected to a printed circuit board, such as the main logic board of a mobile phone, using a second connector 201. A bonding material 196, such as an adhesive material, is disposed on first surface 189 of connector 188. When connector 188 is mated and electrically interconnected to module 189, bonding material 196 is used to retain connector in a compressed and actuated condition against the mating surface of module 186 without external mounting or clamping hardware. The bonding process may be almost instantaneous, such as can occur with a pressure sensitive adhesive, or it may require certain bonding and curing conditions, such as the application of heat and/or pressure over a specific duration of time coupled. In one embodiment, bonding material 196 comprises a bond ply material, comprised of a layer of a modified acrylic adhesive attached to each side of a polyimide film. The modified acrylic material may be a B-staged material, where the adhesive is partially cured so that it can be easily handled during assembly. When bonding material 196 is attached to the connector 188, sufficient temperature and/or pressure is applied to provide a temporary bond to first surface 189 of connector 188, but such that the cure state of the modified acrylic adhesive is not significantly advanced. When the connector is subsequently aligned to and mated with the module, a sufficient bonding and curing process, such as a lamination process involving elevated temperature and/or pressure, would be utilized to achieve a robust adhesive bond and full curing of the acrylic adhesive. In another embodiment, the bond ply material includes a B-staged epoxy material in place of a modified acrylic adhesive.

FIG. 17 shows a drawing of an expanded view of the connector 188 from FIG. 16. In this figure, the bonding material 196 does not overlie the proximal ends 194 of electrical spring contacts 192, although in other embodiments it may. Bonding material 196 is disposed in three strips on the first surface 189 of connector 188, and there are two large openings in bonding material 196, one for each row of electrical spring contacts. Other configurations are also embodied in the teachings of the present invention.

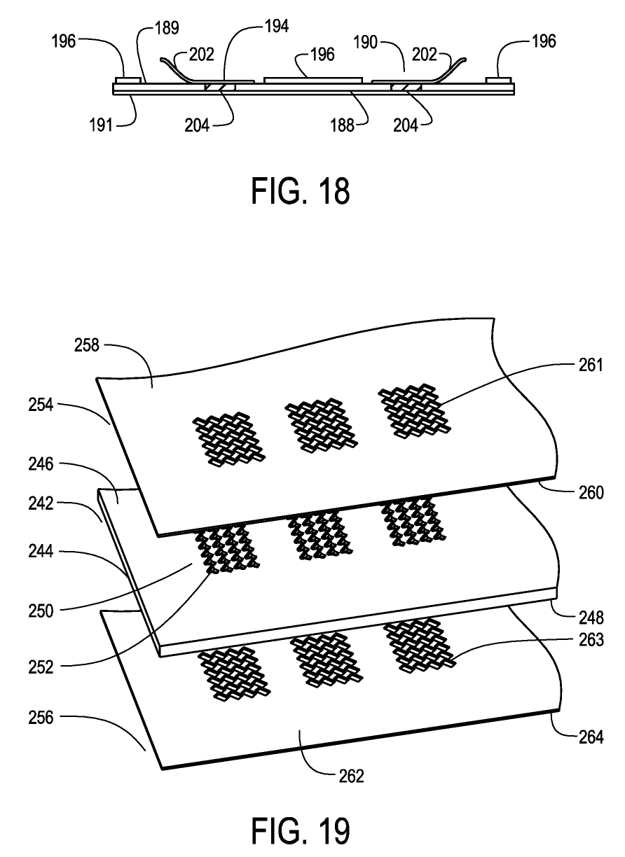

FIG. 18 shows a drawing of a cross-sectional view of the connector 188 from FIG. 16. Electrical spring contacts 190 comprise proximal ends 194 attached to a first surface 189 of connector 188. Interconnection material 204, which may be a plated metal or a solder or conductive adhesive or other interconnection material, allows electrical connection between electrical spring contacts 190 and a conductive interconnection terminals on a second surface of connector 188, where interconnection to a circuit element 191 such as an FPC or a PCB can be made. Bonding material 196 is disposed on first surface 189 of connector 188, with openings for electrical spring contacts 190.

FIG. 19 shows a drawing of a perspective view of a portion of the connector structure to facilitate description of a method of manufacture of an embodiment of the present invention. A connector manufacturing panel 242 may comprise one or several connector electrical spring contact arrays 250 disposed on a substrate 244. Contact arrays 250 may represent separate connectors which are manufactured on a single panel, and subsequently singulated into separate connectors, or multiple arrays may be part of a single connector, for example, signal array and power arrays. Contact arrays 250 comprise elastic, conductive spring contacts 252 disposed on a first surface 246 of substrate 244. Corresponding electrical contact arrays are disposed on second surface 248 of substrate 242, and at least a portion of the individual contact elements on first surface 246 are electrically interconnected to individual contact elements on second surface 248. Sheet 254 is a bonding material having a first surface 258 and a second opposing surface 260, and a plurality of openings 261 substantially aligned with contacts 252 in contact arrays 250 on first surface 246 of connector substrate 244. Bonding material sheet 254 may be a sheet adhesive, such as a modified acrylic sheet adhesive, or an epoxy material, such as a woven glass reinforced, B-staged epoxy prepreg. Sheet 254 may also be a pressure sensitive adhesive, such as a double sided adhesive tape or film. Sheet 254 may also be a bond ply material, such as a film of polyimide with a layer of a B-staged, modified acrylic adhesive on each opposing surface, such as is manufactured by DuPont under the trade name Pyralux® Bond Ply adhesive. Sheet 254 is aligned to connector substrate 244 such that contacts 252 are substantially registered to the openings 261. Openings 261 may include one opening for each contact, or may include large openings that accommodate several contacts. Sheet 254 is bonded to first surface 246 of connector substrate 244. In the case of a pressure sensitive adhesive, a release layer may be removed from second surface 260 of the sheet 254, exposing the adhesive, and pressure would be applied to sheet 254 to form an immediate bond to first surface 246 of connector substrate 244. In the case of an adhesive or bond ply adhesive comprising a thermosetting adhesive such as a B-staged epoxy or a B-staged modified acrylic, the second surface 260 of sheet 254 may be tack laminated to first surface 246 of connector substrate 244 so that it remains in place but the adhesive remains at a B-staged curing condition and can subsequently be bonded and fully cured. Other types of adhesives may also be used, including other thermosetting adhesives, cyanoacrylate adhesives, thermoplastic adhesives, or other types of adhesives that may be known to one skilled in the art. Bonding sheet 254 may be used to bond first surface 246 of connector 242 to a first mating circuit element, such as a printed circuit board or a flexible printed circuit or an electronic module or package substrate, with the electrical spring contacts 252 in a compressed configuration and aligned with electrical interconnection terminals on the first mating circuit element, in order to form low resistance and stable electrical interconnections between the electrical contacts 252 on first surface 246 and the electrical interconnection terminals on the first mating circuit element.

A second sheet material 256 having a first surface 262 and a second, opposing surface 264, also has a plurality of openings 263 which are substantially aligned to electrical spring contacts (not visible in this view) disposed on second surface 248 of connector substrate 244. Sheet material 256 may be a bonding material, such as a bond-ply material, as described for sheet material 254 which is laminated to the opposing first surface 246 of connector substrate 244. As such, it may be a sheet adhesive, or a bond ply adhesive with an adhesive film on either side of a support film, such as polyimide. As such, the sheet 256 may be used to bond connector second surface 248 to a second mating circuit element. In an alternative embodiment, sheet 256 is a coverlay material, comprised of a bonding material on first surface 262, and a non-bonding material, such as a fully cured thermosetting polyimide, on second surface 264. In this embodiment, first surface 262 of sheet 256 would be aligned and bonded to second surface 248 of connector manufacturing panel 242. Outer surface 264 of sheet 256 would not form a bond to the surface of a second mating circuit element, but would serve as a hard compression stop to prevent over-compression of the electrical spring contacts on second surface 248 of connector panel 242. In this embodiment, first surface 260 of sheet 254 would be bonded to first surface 246 of connector panel 252, and second surface 258 of sheet 254 would be bonded to a mating circuit element, forming a permanent electrical interconnection between the connector and the mating circuit element; however, second surface 264 of second sheet 256 residing on second surface 248 of connector panel 242 would form a separable interconnection with a second mating circuit element.

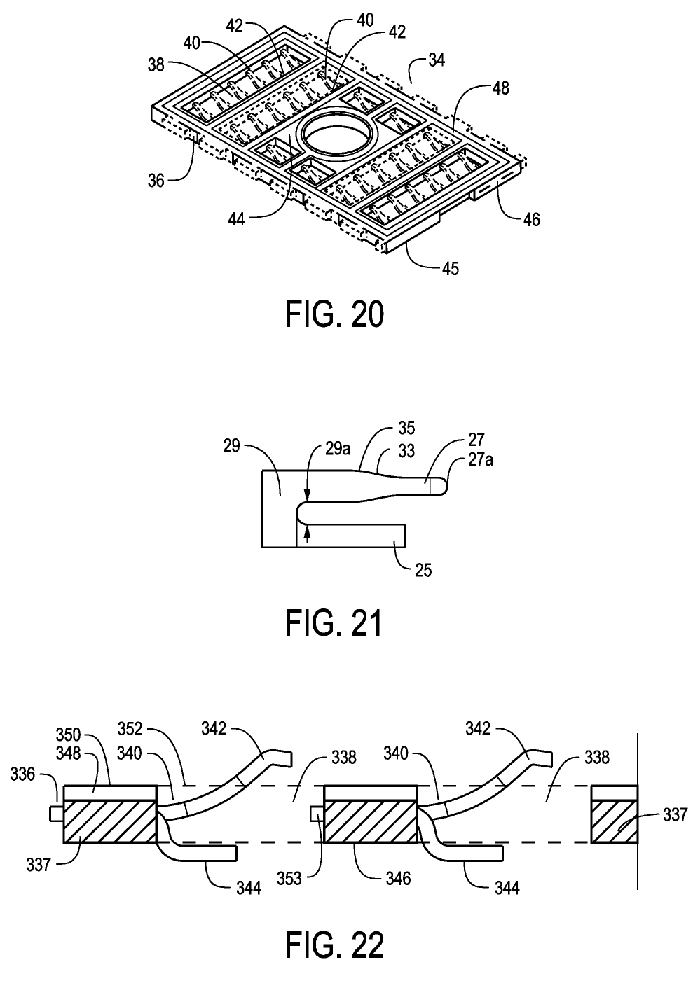

FIG. 20 is a drawing showing a perspective view of a connector 34 according to another embodiment of the present invention, and incorporates without prejudice elements of provisional U.S. Patent Application No. 62/163,539, entitled “Low Profile, Normal Force Connector”, and with a filing date of May 19, 2015. Electrical contact distal ends 40 are elastic contacts, and emanate from a plane 46 within the middle of the insulative connector body 36 through openings 38 in insulative connector body 36 to a point above the first surface 44 of the connector body 36. Contacts proximal ends 42 form a unitary body with distal ends 40, as shown in FIG. 21, which is a drawing of a top view of an individual electrical contact from the connector of this embodiment. Contact proximal ends 42 protrude through openings 38 in connector body 36 to a point slightly proud of second surface 45 of connector body 36. Proximal ends 42 may be relatively inelastic, and may be used as solder terminals to surface mount connector 34 to a first mating circuit element, such as a printed circuit board or a flexible printed circuit, using solder reflow methods. Contact distal ends 40 are elastic, and may be compressed against, and electrically interconnected to, conductive interconnection terminals on a mating circuit element. A bonding material 48 is disposed upon first surface 44 of connector body 36, with openings similar to openings 38 in connector body 36, and is used to form a bond between first surface 44 of connector 34 and a first, mating surface of a mating circuit element, such as a printed circuit board or a flexible printed circuit, to hold distal ends 40 of electrical spring contacts in compression against mating conductive terminals on a mating circuit element. Bonding material 48 may be an adhesive, such as a modified acrylic adhesive or an epoxy-based adhesive. In one embodiment, bonding material 48 is a bond ply material. It may alternatively be a pressure sensitive adhesive. Insulative connector body 36 may be comprised of molded polymer, such as a liquid crystal polymer. The connector 34 shown in FIG. 20 has 28 contact positions, arranged as four rows of six contacts each and two rows of two contacts each, for illustrative purposes only, but the invention is applicable to many other connector designs with differing number of contacts and different contact arrangements.

FIG. 21 shows a drawing of a top view of an electrical contact from one embodiment of the present invention, as illustrated in FIG. 20. Electrical contact 35 has a proximal end 25, a middle section 29, and a distal end 27. Distal end 27 is an elastic spring contact, such as a cantilever beam, and protrudes out of the page toward the viewer of the drawing. Proximal end 25 is a relatively inelastic contact, and protrudes downward away from the viewer of the drawing. Proximal end 25 may be used as a soldering terminal to permanently mount the connector containing an array of these contacts 35 to a circuit element, using surface mount soldering or other means. Distal end 27 and proximal end 25 are approximately parallel to each other, and separated by an air gap 29A. Distal end 27, middle section 29 and proximal end 25 form a unitary body.

FIG. 22 shows a drawing of a cross-sectional view of a portion of the connector from FIG. 20. Connector 336 has an insulative body 337, which may be a molded or machined polymer, such as liquid crystal polymer. Contacts 340 comprise distal ends 342, middle sections 353, and proximal ends 344. Distal ends 342 are elastic, cantilever beam-like conductive spring contacts, while proximal ends 344 are relatively inelastic contact terminals, and may be utilized as solder terminals for surface mount attachment of connector 336 to a circuit element such as a PCB or an FPC. Proximal end 344 of contact 340 protrudes slightly proud of second surface 346 of connector body 337 through opening 338 in connector body 337, and is essentially parallel to surface 346. Distal end 342 of contact 340 protrudes significantly proud of first surface 348 through opening 338 of connector body 337, and is substantially non-parallel with surface 348, as illustrated by hashed lines 352. Middle section 353 of contact 340 is located approximately central to the cross sectional thickness of connector body 337, and is substantially surrounded by and bonded to the connector body, such as might be achieved by molding the connector body around middle sections 353, so that contact 340 is captured by and retained tightly within connector body 337, maintaining its position and orientation. A bonding material 350 is disposed on first surface 348 of connector body 337. Bonding material 350 may be an adhesive material, such as a modified acrylic adhesive, an epoxy, a PSA, or other adhesive composition. The adhesive material may be applied as a film or a sheet, such as a B-staged thermosetting material or a thermoplastic material, or it may be applied as a liquid or paste material by dispensing, spraying, printing, jetting, or by other application means. Bonding material 350 may alternatively be a bond ply material. Openings are provided in bonding material 350 substantially corresponding to openings 338 in connector body 337, such that the bonding material 350 does not interfere with movement of distal portion 342 of contact 340 during compression.

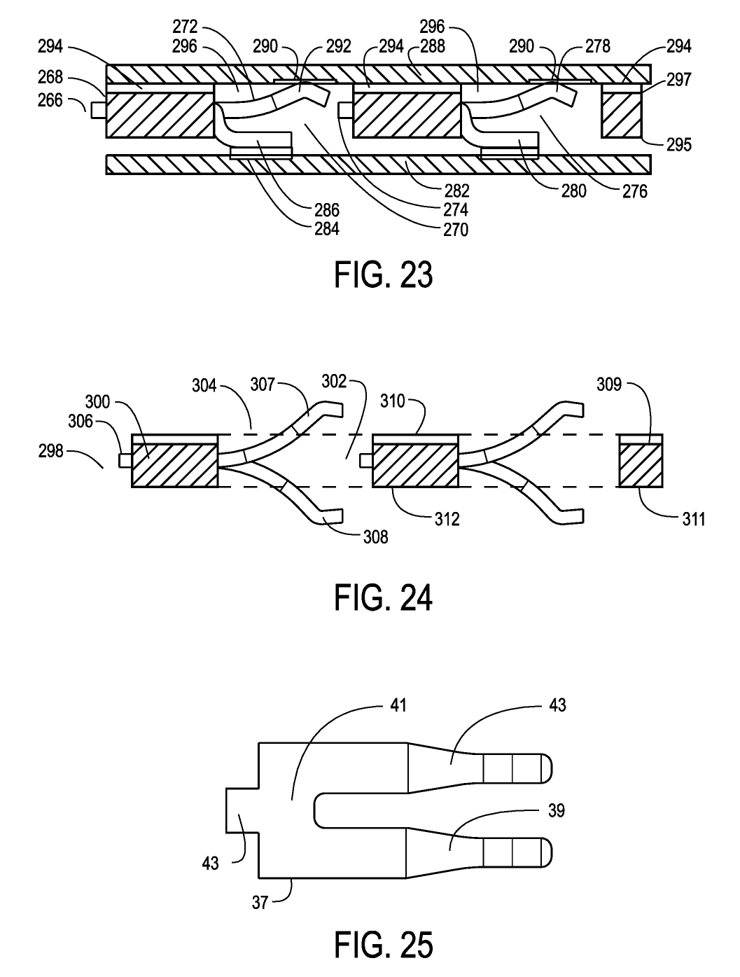

FIG. 23 shows a drawing of a cross-sectional view of the connector from FIG. 22 subsequent to mating and bonding it to mating circuit elements. Connector 266 comprises a plurality of electrical contacts 272 comprising middle section 274 substantially encased in insulative connector body 268 of connector 266, distal end 278 emanating above a first surface 297 of connector body 268, and proximal end 280 emanating above a second surface 295 of connector body 268, through openings 270 in connector body 268. Second surface 295 of connector 266 is surface mounted onto mating circuit element 282, through interconnection of contact 272 proximal ends 280 to conductive interconnection terminals 284 on a surface of mating circuit element 282. Mating circuit element 282 may be a printed circuit, such as a rigid PCB or a flexible printed circuit, or it may be a package substrate or a module or other type of circuit element. Proximal ends 280 of contacts 272 of connector 266 may be interconnected to terminals 284 using a conductive interconnection material 286 such as solder or conductive adhesive. Connector 266 is electrically interconnected to a second, opposing mating circuit element 288 by aligning and compressing distal ends 278 of contacts 272 of connector 266 against conductive interconnection terminals 290 of mating circuit element 288 through application of force between connector first surface 297 and mating circuit element 288, said force being applied normal to the first surface 297 of connector body 268. Bonding material 294 is disposed between first surface 297 of connector body 268 and mating circuit element 288, and may comprise an adhesive material. Bonding material 294 is treated to form an adhesive bond between mating circuit element 288 and first surface 297 of connector 266 so as to maintain distal ends 278 of contacts 272 in alignment with and compressed against conductive interconnection terminals 290 on circuit element 288, forming stable and low resistance electrical interconnections. The use of bonding material 294 to maintain the interconnection between connector 266 and circuit element 288 eliminates the requirement for any extraneous clamping hardware, minimizing connector footprint and minimizing real estate required on circuit elements 288 and 282 for the interconnections. In one embodiment, circuit element 288 is a miniaturized and thermally sensitive component, such as an optical interconnect assembly or a flash memory module, which may be damaged by normal surface mount solder reflow temperatures. In this embodiment, connector 266 is first surface mounted to a less thermally sensitive circuit element, such as a main logic PCB 282. Subsequently, thermally sensitive circuit element 288 is interconnected to connector 266 by application of normal force between first surface 297 of connector 266 and mating circuit element 288, and by application of appropriate bonding conditions, such as temperature and/or pressure, to form an adhesive bond between connector 266 and circuit element 288 with bonding material 294. In a preferred embodiment, bonding material 294 forms an adhesive bond at temperatures substantially less than the reflow temperature for lead free solders, and preferably at a temperature of less than 200 degrees Celsius. In another embodiment, the bonding material 294 is a modified acrylic adhesive bond ply material, such as DuPont Pyralux® FR or Pyralux® LF.

FIG. 24 shows a drawing of a cross sectional view of a connector of one embodiment of the present invention. Connector 298 is intended to form electrical interconnections between two distinct circuit elements, such as two printed circuit boards, or a PCB and an FPC, or a PCB and a module. Connector 298 has an insulative connector body 300, which may be a molded or machined polymer, such as a liquid crystal polymer, or other insulating element such as a laminate printed circuit board structure. Electrical contact element 304 has a middle section 306 and two distal ends 307 and 308, forming a unitary body as shown in a drawing of a top view in FIG. 25. The two distal ends 307 and 308 of contact 304 emanate respectively above opposing first surface 309 and second surface 311 of connector 298 through openings 302 in connector body 300, and both distal ends 307 and 308 are substantially elastic, and may be substantially similar to three dimensional cantilever beams, or may be comprised of other elastic spring types. Bonding material 310 is disposed on a first surface 309 of connector body 300. Second surface 312 of connector body 300 does not have a bonding material disposed upon it. Second surface 312 and contact distal ends 308 may form a separable electrical interconnection to a mating circuit element, through compression of distal ends 308 against conductive circuit terminals on the mating circuit element, and through maintenance of the compressive force through, for example, clamping hardware such as spring clamps or screws. First surface 309 of connector 298 may form a permanent electrical interconnection to a second circuit element, through compression of distal ends 307 against conductive circuit terminals on the second mating circuit element, and through maintenance of the compressive force by forming and adhesive bond between bonding material 310 on first surface 309 of connector 298 and the mating surface of the second mating circuit element.

FIG. 25 shows a drawing of a top view of an elastic spring contact from the connector shown in FIG. 24. Contact 37 has a middle section, 41, and distal ends 43 and 39, comprising a unitary body. Distal end 43 emanates upward toward the viewer of this figure, and distal end 39 emanates downward, away from the viewer of this figure.

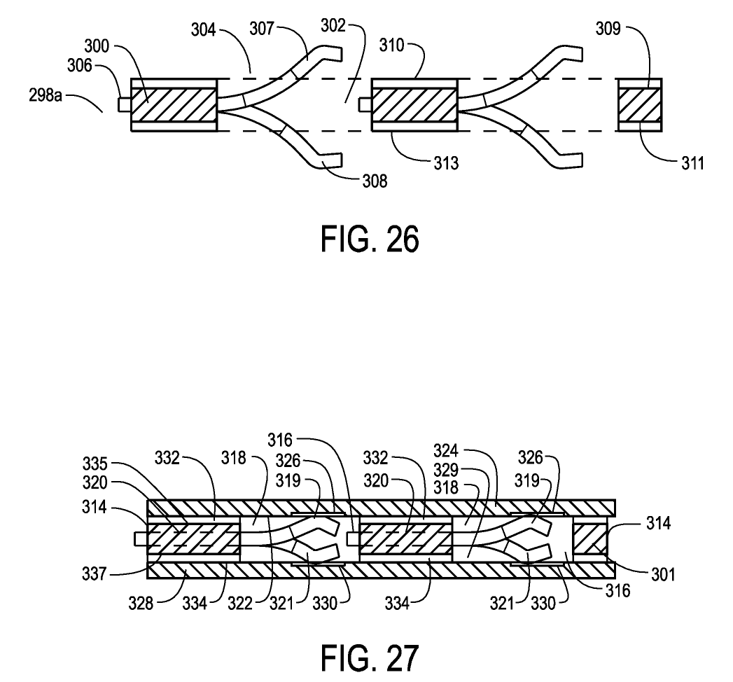

FIG. 26 shows a drawing of a cross-sectional view of a connector of an alternative embodiment of the present invention. Connector 298A in FIG. 26 is substantially similar to connector 298 in FIG. 24, except that both first surface 309 and second surface 311 of connector body 300 of connector 298A in FIG. 26 have a bonding material disposed upon them. First surface 309 has bonding material 310 disposed upon it, and second surface 311 has bonding material 313 disposed upon it; whereas, in the connector 298 in FIG. 24, only first surface 309 has disposed upon it a bonding material, 310. Bonding material 310 and bonding material 313 may be identical in composition, or they may be different, such that they have different bonding temperatures. For example, it may be advantageous to interconnect surface 309 of connector 298A to a mating circuit element prior to interconnecting second surface 311 of connector 298A to a second circuit element, and it may be further advantageous that the bonding temperature of material 310 on surface 309 is higher than bonding temperature for bonding material 313 on second surface 311.

FIG. 27 shows a drawing of a cross sectional view of the connector from FIG. 26 after interconnection to two mating circuit elements. Connector 314 comprises electrical contacts 318 with proximal ends 320 mounted in insulative connector body 301 and distal ends 319 and 321 compressed against mating terminals 326 and 330 respectively of mating circuit elements 324 and 328. Bonding material 332 is disposed between first surface 335 of connector body 301 and mating circuit element 324. Bonding material 334 is disposed between second surface 337 of connector body 301 and second mating circuit element 328. Normal force is applied between mating circuit elements 328 and 324 and connector 314, and the assembly undergoes process conditions while under compression so as to form adhesive bonds between connector 314 and mating circuit elements 324 and 328 using bonding materials 332 and 334. Bonding may be done concurrently or sequentially.

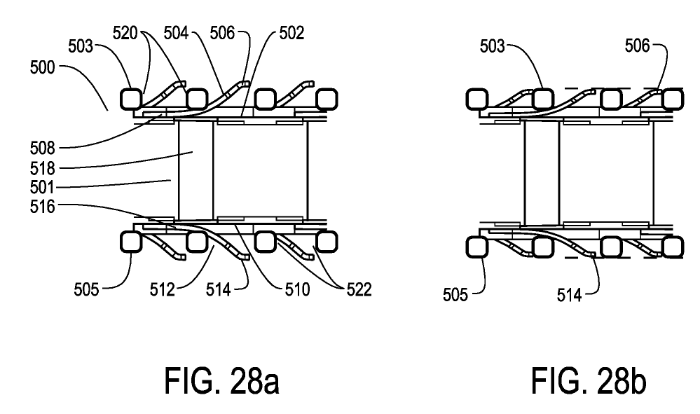

FIG. 28 shows a drawing of a cross-sectional view of a connector of the present invention. Connector 500 has an insulative connector body 501, which may comprise a laminate material such as a printed circuit board substrate material. For example, connector body 501 may be comprised of an FR4 or similar printed circuit substrate material, or it may be a flexible material such as polyimide, or a rigid molded material such as liquid crystal polymer.

Connector body 501 has a first surface 502 and a second surface 510. A plurality of electrical spring contacts 504 are disposed on first surface 502, and a plurality of electrical spring contacts 512 are disposed on second surface 510. Contacts 504 have a proximal end 508 which is affixed to first surface 502 of connector body 501, and a distal end 506 emanating outwardly above first surface 502. Contacts 512 have a proximal end 516 which is affixed to a second surface 510 of connector body 501, and a distal end 514 emanating outwardly above second surface 510. At least one contact 504 on first surface 502 is electrically interconnected to at least one contact 512 on second surface 510 through an interconnection circuit path 518, which may be a plated via such as a plated through hole. A first non-conductive bonding material 503 is disposed upon first surface 502 of connector body 501. A non-conductive material is disposed on second surface 510 of connector body 501. As shown in FIG. 28A, the distal ends 506 of contacts 504 on first surface 502 of connector 500 emanate above the surface of bonding material 503 (further from surface 502 than the thickness of bonding material 503) when the contacts are in their un-compressed state. Likewise, the distal ends 514 of contacts 512 on second surface 510 of connector 500 emanate above the surface of non-conductive material 505. Bonding material 503 on first surface 502 of connector body 501 may be a polymer material which is bondable, such as an adhesive material. It may be a thermoplastic material which forms an adhesive bond through melting and re-solidification, or it may be a thermosetting material which forms an adhesive bond through a curing process, which may include cross-linking. In another embodiment, bonding material 503 is a pressure sensitive adhesive, and can form a near instantaneous bond. In another embodiment, bonding material 503 is a pressure sensitive adhesive which forms an initial bond, and for which bond strength can be increased by a post-bonding treatment, such as a thermal cycle. Bonding material 503 has openings 520 through which emanate distal ends 506 of contacts 504, and which allow free movement of contacts 504 during compression. Non-conductive material 505 on second surface 510 of connector body 501 may be a non-bondable polymer, such as a polyimide. Alternatively, material 505 may be a coverlay material which has an outward facing layer of polyimide which is bonded to the second surface 510 of connector body 501, such as with a modified acrylic adhesive. Non-conductive material 505 has openings 522 through which emanate distal ends 514 of contacts 512, and which allow free movement of contacts 512 during compression and release.

When first surface 502 of connector 500 is mated to a mating circuit element, such as an FPC or a PCB, normal force is applied to compress distal ends 506 of elastic, conductive spring contacts 504 against conductive interconnection terminals on the mating circuit element, in order to form low resistance electrical interconnections. While surface 502 is compressed against the mating circuit element, bonding material 503 may be treated so as to form an adhesive bond to the mating circuit element. The adhesive bond preferably has sufficient adhesive strength and the bond is durable enough to maintain the springs in the fully compressed position against the mating circuit terminals throughout the useful life of the product.

When second surface 510 of connector 500 is mated to a second mating circuit element, such as an FPC or a PCB or a module or a substrate, normal force is applied to compress distal ends 514 of elastic, conductive spring contacts 512 against conductive interconnection terminals on the second mating circuit element, in order to form low resistance electrical interconnections. Since non-conductive material 505 is not a bonding material, it does not form an adhesive bond to the second mating circuit element, and external clamping hardware is necessary to maintain normal force between the connector and the circuit element to maintain a low resistant and stable electrical interconnection. This electrical interconnection can therefore be separated and reconnected, such as may be desirable for testing, repair, and/or rework of elements in an electronic system.

In another embodiment of the present invention, both materials 503 and 505 are bonding materials, and are designed to form adhesive bonds to mating circuit elements so as to maintain electrical spring contacts 504 on first connector surface 502 and electrical spring contacts 512 on second connector surface in a compressed and mating configuration against interconnection terminals on mating circuit elements.

Materials 503 and 505 also function as compression hard stops for electrical spring contacts 504 and 512 respectively. The thickness of materials 503 and 505 may be chosen such that they allow sufficient displacement of distal ends 506 and 514 of spring contacts 504 and 512 respectively, such that they apply enough pressure and sufficiently wipe against mating conductive circuit terminals on mating circuit elements, yet to prevent over-compression of the spring contacts 504 and 512 whereby they may yield plastically and may lose mechanical integrity or electrical integrity of the interconnection.

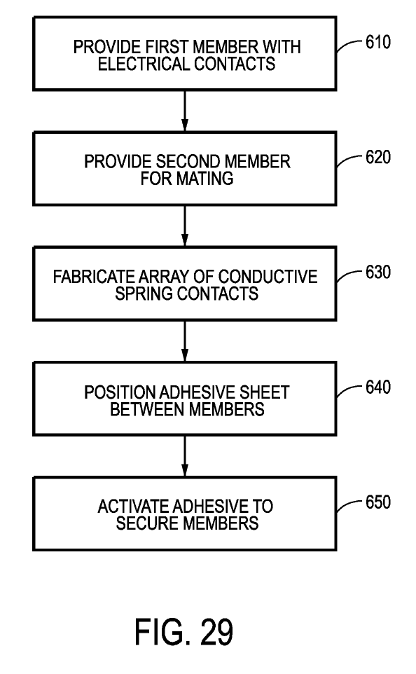

FIG. 29 is a flow chart showing one method of creating an electrical connection using the present invention. A first member is provided with a plurality of spaced electrical terminations, such as contact terminals or pads, usually mounted on a planar substrate at block 610. A second mating member includes an insulating substrate which often is also planar at block 620. A plurality of conductive spring contacts are formed in the desired shape (preferably using a manufacturing process taught in Neoconix' patents referenced above) at block 630. The spring contacts are located on the insulating substrate of the second member so as to mate with the electrical terminations carried on the first member when the first member is assembled to the second member. A sheet preferably carrying b-staged adhesive on both sides is positioned between the first member and the second member at block 640. Then, at block 650, the adhesive is activated to secure the first member to the second member when the first member is assembled with the second member, with the adhesive providing a normal force between the first member and the second member to maintain the spring contacts in compressed states to provide a low-resistance electrical connection between each spring contact and the corresponding electrical termination. The activation of the adhesive may be through heat for a thermosetting or thermoplastic adhesive material (or pressure for a pressure-sensitive adhesive material)—and the activation of the adhesive may involve activating the two layers of adhesive at substantially the same time or at sequential times, if desired, such as by having a first adhesive layer which is activated by heat at a lower temperature at a first time and a second layer of adhesive which is activated by heat at a higher temperature at a second time. Using a sheet containing thermoplastic material allows for the members to be decoupled later, if desired.

Of course, many modifications and adaptations to the preferred embodiment disclosed above are possible without departing from the spirit of the present invention, Further, some features of the disclosed embodiment can be used to advantage without the corresponding use of other features disclosed in the description. As such, the disclosure should be considered as a teaching of various aspects of the present invention which can be put together in various ways by a man of ordinary skill in the art to which this invention applies. For example, the electrical connection may be made semi-permanent if desired, allowing for the connection to be suspended for one reason or another—and then for the connection to be re-assembled as desired, for example, with a different connection. As such, the present invention may use a thermoplastic material for the bonding compound to allow for the separation of the elements if desired. Alternatively, if disconnection of elements is not desired, then the bonding agent may be a thermo-setting material. Also, the method of creating the connection has been disclosed with some specificity, but other securing materials are known and can be used to advantage—and the method of securing the components together might be pressure in place of (or in addition to) heat to engage the bonding material. Thus it will be appreciated by those of ordinary skill in the relevant art that many modifications to the present invention can be used without departing from the spirit of the present invention and it is possible to use some components of the invention without using other components disclosed herein.

Having thus described the invention, what is claimed is:

1. An electrical connector coupling a first member having a plurality of spaced electrical contacts and a second member which carries a plurality of spring contacts having a spacing to engage the spaced contacts to conduct electrical signals therebetween, the electrical connector providing a normal force between the first member and the second member without a mechanical clamp member the electrical connector comprising:
a layer of adhesive material disposed between the first member and the second member, said layer of adhesive material securing the first member to the second member and providing a normal force on the spring contacts and maintain the spring contacts in electrical connection with the spaced electrical contacts on the first member; and
the layer of adhesive material having at least one aperture to allow the electrical spring contacts to project through the layer.

2. An electrical connector of the type described in claim 1 wherein the adhesive is carried on both sides of a carrier sheet.

3. An electrical connector of the type described in claim 1 wherein the adhesive comprises a thermosetting material.

4. An electrical connector of the type described in claim 1 wherein the adhesive comprises a thermoplastic material.

5. An electrical connector of the type described in claim 1 wherein the adhesive comprises a first adhesive and a second, different adhesive, where the first adhesive is activated without activating the second adhesive.

6. An electrical connector of the type described in claim 1 where the thickness of the adhesive is chosen to limit the movement of the electrical contacts to move within an elastic region of the electrical contacts.

7. An electrical connector of the type described in claim 1 wherein the layer of adhesive material provides a hard stop to limit the travel of the connector members.

8. An electrical connector of the type described in claim 1 wherein the adhesive layer has a first portion which is used for tacking the adhesive layer in place and a second portion for securing the layer to the first member.

9. An electrical connector of the type described in claim 1 wherein the adhesive material includes a flame retardant adhesive material.

10. An electrical connector of the type described in claim 1 wherein the adhesive comprises a B-staged acrylic adhesive.

11. A method of electrically coupling a first member having a plurality of electrical contacts spaced along a planar substrate to a plurality of three-dimensional spring contacts carried on a second member, the steps of the method comprising:
forming a flat sheet of conductive material into a plurality of three-dimensional electrically conductive spring contacts;
assembling the first member and the second member after positioning the sheet of spring contacts on the second substrate with the plurality of spring contacts located to mate with the plurality of electrical contacts on the first member;
placing a sheet carrying adhesive material between the first member and the second member; and
activating the adhesive to secure the first member to the second member with the adhesive material providing a normal force on the assembled first and second members to provide a force on the spring members to provide a low-resistance interconnection between the electrical contacts on the first member and the respective spring contacts on the second member without a separate mechanical clamp securing the first member and second member together.

12. A method including the steps of claim 11 wherein the adhesive comprises a thermosetting adhesive allowing the members to permanently adhere.

13. A method including the steps of claim 11 wherein the adhesive comprises a thermoplastic adhesive.

14. A method including the steps of claim 12 including the additional step of releasing the thermoplastic adhesive, allowing the first member and the second member to be separated.

15. A method including the steps of claim 14 wherein the process includes the step of heating the thermoplastic adhesive to release its adhesion.

16. A method including the steps of claim 11 wherein the process includes the step of providing the sheet carrying adhesive material with adhesive material on both sides of the sheet.

17. A method including the steps of claim 16 wherein the step of providing adhesive material on two sides includes the step of using a first adhesive material on one side and a different adhesive material on the other side.

18. A method including the steps of claim 17 wherein the process of activating the adhesive includes activating the first adhesive material at one time with the activation of the second adhesive material being activated at a different time.

19. A method including the steps of claim 11 wherein the step of activating the adhesive includes a step of activating some adhesive material to provide a tacking of the adhesive sheet in a desired location and later a second activation to secure the adhesive sheet in place.

20. A method including the steps of claim 11 wherein the step of activating the adhesive includes the step of activating a B-staged adhesive material.

21. A method including the steps of claim 11 where the steps of the method include using a flame retardant adhesive.

22. A method of electrically coupling a first electrical connector having a plurality of electrical contacts spaced along a planar substrate to a plurality of three-dimensional spring contacts carried on a second substrate of a second electrical connector, the steps of the method comprising:
forming a flat sheet of conductive material into a plurality of three-dimensional electrically conductive spring contacts;
singulating the electrical contacts on the sheet into a plurality of separate electrically conductive spring contacts;
assembling the first electrical connector and the second electrical connector after positioning the sheet of spring contacts on the second substrate with the plurality of spring contacts located to mate with the plurality of electrical contacts on the first electrical connector;
placing a sheet carrying adhesive material between the first electrical connector and the second electrical connector; and
activating the adhesive to secure the first electrical connector to the second electrical connector with the adhesive material providing a normal force on the assembled first and second electrical connectors to provide a force on the spring electrical contacts to provide a low-resistance interconnection between the electrical contacts on the first electrical connector and the respective spring contacts on the second electrical connector. without a separate mechanical clamp securing the first electrical connector and second electrical connector together.

23. A method including the steps of claim 22 wherein the process includes the step of providing the sheet carrying adhesive material with adhesive material on both sides of the sheet.

24. A method including the steps of claim 23 wherein the step of providing adhesive material on two sides includes the step of using a first adhesive material on one side and a different adhesive material on the other side.

25. A method including the steps of claim 24 wherein the process of activating the adhesive includes activating the first adhesive material at one time with the activation of the second adhesive material being activated at a different time.

26. A method including the steps of claim 22 wherein the method includes providing a hard stop limiting the movement of the first and second electrical connectors using the sheet carrying adhesive material to limit the movement of one electrical connector with respect to the other electrical connector.

27. A method including the steps of claim 26 wherein the method includes the step of limiting the deformation of the elastic electrical spring contacts to the plastic range.

28. A method including the steps of claim 22 wherein the method includes providing a plurality of apertures in the adhesive material, the number f such apertures based on the number of elastic spring contacts.

29. A method including the steps of claim 22 wherein the method includes the step of providing a sheet of adhesive bonding material which comprises a layer of polyimide film carrying at least one layer of epoxy adhesive.

30. A method including the steps of claim 29 wherein the method further includes providing a second adhesive on the polyimide film.

31. A method including the steps of claim 30 where the second adhesive is different from the epoxy layer and has a different activation point.

32. A method including the steps of claim 31 wherein the method includes a step of activating the second adhesive at a different time from the activation of the epoxy adhesive.
